(19) United States
(12) Patent Application Publication
(10) Pub. No.: US 2017/0162927 A1
(43) Pub. Date: Jun. 8, 2017

(54) Air Gap Creation In Electronic Devices

(71) Applicant: Hatem Mohamed Aead, Woodland Park, NJ (US)

(72) Inventor: Hatem Mohamed Aead, Woodland Park, NJ (US)

(21) Appl. No.: 15/437,445

(22) Filed: Feb. 21, 2017

Related U.S. Application Data
(62) Division of application No. 14/292,839, filed on May 31, 2014.

(51) Int. Cl. H01P 11/00; H05K 1/02; H05K 3/40; H05K 3/00; H05K 3/30; H01P 3/08; H05K 1/03

(52) U.S. Cl. CPC H01P 11/003; H01P 3/08; H05K 1/0243; H05K 1/0306; H05K 3/0044; H05K 3/30; H05K 3/4038; H05K 2201/10022; H05K 2201/1006

(57) ABSTRACT

A method for creating an air gap in an electronic device, for example, a passive electronic component chip (PECC) for high frequency microwave transmission is provided. Electronic circuitry of a passive electronic component, for example, a termination, an attenuator, etc., is fabricated in a predetermined configuration on a single layer of a substrate to create the PECC. An air gap of configurable dimensions is created at a configurable location on the substrate by dicing the substrate at the configurable location to create a suspended substrate-like environment in the PECC. The created air gap reduces the dielectric constant at the configurable location and reduces capacitance of the substrate along areas located directly above the air gap. The created air gap also reduces a loss tangent, high frequency attenuation, and electromagnetic fields near a ground plane of the PECC, creates a wide strip dimension, and creates less stringent tolerance in the PECC.

### CROSS REFERENCE TO RELATED APPLICATIONS

This application is a divisional application of U.S. patent application Ser. No. 14/292,839 titled “Air gap creation in electronic devices” filed in the United States Patent and Trademark Office on May 31, 2014. The specification of the above referenced patent application is incorporated herein by reference in its entirety.

### BACKGROUND

Conventional methods for designing high power, high frequency, and wide bandwidth electronic devices, for example, passive electronic components such as terminations, attenuators, resistors, power dividers, directional couplers, filters, etc., use high thermal conductivity ceramic substrates made of materials, for example, alumina, beryllium oxide (BeO), aluminum nitride (AlN), etc. However, the materials used in ceramic substrates have relatively high dielectric constants. The dielectric constant of a material, also referred to as “relative permittivity”, is a ratio of an amount of electrical energy stored in a material by an applied voltage, relative to an amount of electrical energy stored in a vacuum. The dielectric constant of a material is also a ratio of capacitance of a capacitor using the material as a dielectric, compared to a similar capacitor that has a vacuum as its dielectric.

Ceramic substrate materials are typically capacitive materials with high dielectric losses, especially at high frequencies, for example, radio frequency (RF), microwave frequency, millimeter wave frequency, etc. The aforementioned problems associated with ceramic substrates preclude a design engineer from increasing performance of passive electronic components fabricated on ceramic substrates, and from meeting continuous technological demands. Hence, the passive electronic components fabricated on ceramic substrates have a limited performance, for example, in terms of frequency bandwidth, voltage standing wave ratio (VSWR), attenuation, etc. Hence, there is a need for a cost effective, efficient, and an uncomplicated method for designing passive electronic components with high frequency and wide bandwidth using a substrate made of a ceramic material.

In the microchip fabrication industry, a method for increasing performance of chips comprises insertion of air gaps in the chips, as air gaps have the lowest dielectric constant after vacuum. An air gap minimizes parasitic coupling in a chip and reduces electrical leakage and mechanical stress when compared with chips without an air gap. Air gaps are inserted, for example, by insulating copper wires within a chip with vacuum holes. The insertion of air gaps results in reduction of capacitance, thereby allowing chips to work faster and draw less power.

Different air gap formation techniques have varying degrees of complexity. In a conventional method for creating air gaps in chips on a large scale, a polymer material is deposited on an entire substrate wafer, which is later removed to create multiple vacuum holes in the substrate. However, this method is expensive. In a conventional method for fabricating a semiconductor device with an air gap, the air gap is created between metal leads of the semiconductor device to reduce capacitive coupling between the electrically conducting metal leads. Some of the air gap formation techniques typically employ a material disposed between metal lines, which is subsequently removed to create an air gap. Other conventional methods comprise, for example, chemical processes such as plasma-enhanced chemical vapor deposition (PECVD), chemical vapor deposition (CVD), etching, etc. Another method employs a semiconductor material, where a semiconductor material is grown on top of another layer by chemical pre-position to form a unit of a chip package. Depositing one layer on top of another layer minimizes coupling or cross talk in the chip package. An air gap is then formed in the composite layers by etching. Typically, these air gap formation techniques are expensive. There is a need for a cost effective method for creation of air gaps in chip packages.

Hence, there is a long felt but unresolved need for a method for creating an air gap that attains a reduced dielectric constant in a passive electronic component chip configured for high frequency microwave transmission. Furthermore, there is a need for a cost effective, efficient, and uncomplicated method for designing high power, high frequency, and wide bandwidth passive electronic component chips comprising air gaps.

### SUMMARY OF THE INVENTION

This summary is provided to introduce a selection of concepts in a simplified form that are further disclosed in the detailed description of the invention. This summary is not intended to identify key or essential inventive concepts of the claimed subject matter, nor is it intended for determining the scope of the claimed subject matter.

The method disclosed herein addresses the above stated needs for creating an air gap that attains a reduced dielectric constant in an electronic device, for example, a passive electronic component chip configured for high frequency microwave transmission. Furthermore, the method disclosed herein provides a cost effective, efficient, and uncomplicated method for designing high power, high frequency, and wide bandwidth passive electronic component chips comprising air gaps.

In the method disclosed herein, a single layer of a substrate configured to house the electronic circuitry of a passive electronic component, for example, a termination, an attenuator, etc., is provided. In an embodiment, a configuration for the electronic circuitry of a passive electronic component is determined for reducing a dielectric constant and thereby reducing capacitance of the passive electronic component chip. In the method disclosed herein, the electronic circuitry of the passive electronic component is fabricated in the determined configuration on the single layer of the substrate to create the passive electronic component chip.

In the method disclosed herein, multiple configurable locations for creating the air gap on the single layer of the substrate are determined. A design engineer selects one of the determined configurable locations on the substrate. An air gap of a configurable dimension is created at the selected location on the substrate, for example, by dicing the single layer of the substrate at the selected location. The air gap is configured to create a suspended substrate-like environment in the passive electronic component chip. The air gap is further configured to attain a reduced dielectric constant at the selected location on the substrate for high frequency microwave transmission, reduce the capacitance of the substrate along the areas located directly above the air gap, reduce a loss tangent, reduce high frequency attenuation, reduce electromagnetic fields near a ground plane of the passive electronic component chip, create a wide strip dimension, and create less stringent tolerance in the passive electronic component chip.

In one or more various aspects, related devices include but are not limited to circuitry for effecting the methods referenced herein; the circuitry can be virtually any combination of hardware configured to effect the herein-referenced methods depending upon the design choices of a design engineer. Also, various structural elements may be employed depending on the design choices of the design engineer.

### BRIEF DESCRIPTION OF THE DRAWINGS

The foregoing summary, as well as the following detailed description of the invention, is better understood when read in conjunction with the appended drawings. For the purpose of illustrating the invention, exemplary constructions of the invention are shown in the drawings. However, the invention is not limited to the specific methods and components disclosed herein. The description of a method step or a component referenced by a numeral in a drawing carries over to the description of that method step or component shown by that same numeral in any subsequent drawing herein.

FIG. 1A illustrates a method for creating an air gap in a passive electronic component chip configured for high frequency microwave transmission.

FIG. 1B illustrates an embodiment of the method for creating an air gap in a passive electronic component chip configured for high frequency microwave transmission.

FIG. 2A exemplarily illustrates a front, top perspective view showing electronic circuitry of a termination fabricated on an upper section of a substrate of a termination chip.

FIG. 2B exemplarily illustrates a layer of epoxy configured to be screen printed on the upper section of the substrate of the termination chip.

FIG. 2C exemplarily illustrates a front, top perspective view of the termination chip, showing the layer of epoxy screen printed on the upper section of the substrate of the termination chip.

FIG. 2D exemplarily illustrates a front, top perspective view of the termination chip, showing an input connector tab and an air gap configured in the substrate of the termination chip.

FIG. 2E exemplarily illustrates a rear, top perspective view of the termination chip, showing the input connector tab and the air gap configured in the substrate of the termination chip.

FIG. 3A exemplarily illustrates a front, top perspective view of a termination chip with an operating frequency of 20 gigahertz, showing components of the electronic circuitry of the termination chip.

FIG. 3B exemplarily illustrates a top plan view of the termination chip with an operating frequency of 20 gigahertz, showing the components of the electronic circuitry of the termination chip.

FIG. 3C exemplarily illustrates a top plan view of the termination chip with an operating frequency of 20 gigahertz, showing the components of the electronic circuitry of the termination chip and an air gap in the termination chip.

FIGS. 3D-3E exemplarily illustrate top plan views of the termination chip with an operating frequency of 20 gigahertz, showing the components of the electronic circuitry of the termination chip and one or more air gaps of dimensions different from the dimensions of the air gap exemplarily illustrated in FIG. 3C.

FIG. 3F exemplarily illustrates a top plan view of the termination chip with an operating frequency of 20 gigahertz, showing positioning of the components of the electronic circuitry of the termination chip at different distances.

FIG. 4A exemplarily illustrates a circuit diagram corresponding to the termination chip shown in FIGS. 3A-3C and FIG. 3F, showing two cascaded T-type resistance networks connected in series in the shape of a cross symbol “+”.

FIGS. 4B-4G exemplarily illustrate circuit diagrams of equivalent circuits of a 50 ohms termination chip shown in FIGS. 3A-3C and FIG. 3F, with an operating frequency of 20 gigahertz.

FIG. 5 exemplarily illustrates a graphical representation of return loss performance of the termination chip with an operating frequency of 20 gigahertz.

FIG. 6A exemplarily illustrates a front, top perspective view of a termination chip with an operating frequency of 30 gigahertz, showing components of the electronic circuitry of the termination chip.

FIG. 6B exemplarily illustrates a top plan view of the termination chip with an operating frequency of 30 gigahertz, showing the components of the electronic circuitry of the termination chip.

FIG. 6C exemplarily illustrates a top plan view of the termination chip with an operating frequency of 30 gigahertz, showing the components of the electronic circuitry of the termination chip and an air gap in the termination chip.

FIG. 7 exemplarily illustrates a graphical representation of return loss performance of the termination chip with an operating frequency of 30 gigahertz.

FIG. 8A exemplarily illustrates a front, top perspective view of a termination chip with an operating frequency of 40 gigahertz, showing components of the electronic circuitry of the termination chip.

FIG. 8B exemplarily illustrates a top plan view of the termination chip with an operating frequency of 40 gigahertz, showing the components of the electronic circuitry of the termination chip.

FIG. 8C exemplarily illustrates a top plan view of the termination chip with an operating frequency of 40 gigahertz, showing the components of the electronic circuitry of the termination chip and an air gap in the termination chip.

FIG. 9 exemplarily illustrates a graphical representation of return loss performance of the termination chip with an operating frequency of 40 gigahertz.

FIG. 10A exemplarily illustrates a front, top perspective view of a termination chip with an operating frequency of 50 gigahertz, showing components of the electronic circuitry of the termination chip.

FIG. 10B exemplarily illustrates a top plan view of the termination chip with an operating frequency of 50 gigahertz, showing the components of the electronic circuitry of the termination chip.

FIG. 10C exemplarily illustrates a top plan view of the termination chip with an operating frequency of 50 gigahertz, showing the components of the electronic circuitry of the termination chip and an air gap in the termination chip.

FIG. 11 exemplarily illustrates a graphical representation of return loss performance of the termination chip with an operating frequency of 50 gigahertz.

FIG. 12A exemplarily illustrates a front, top perspective view of an attenuator chip.

FIG. 12B exemplarily illustrates a rear, top perspective view of the attenuator chip.

FIG. 13A exemplarily illustrates a front, top perspective view of the attenuator chip, showing components of the electronic circuitry of the attenuator chip.

FIG. 13B exemplarily illustrates a top plan view of the attenuator chip, showing the components of the electronic circuitry of the attenuator chip.

FIG. 13C exemplarily illustrates a top plan view of the attenuator chip, showing the components of the electronic circuitry of the attenuator chip and an air gap in the attenuator chip.

FIG. 14A exemplarily illustrates a front, top perspective view of a 20 decibel attenuator chip with an operating frequency of 20 gigahertz.

FIG. 14B exemplarily illustrates a top plan view of the 20 decibel attenuator chip with an operating frequency of 20 gigahertz.

FIG. 14C exemplarily illustrates a top plan view of the 20 decibel attenuator chip with an operating frequency of 20 gigahertz, showing an air gap in the 20 decibel attenuator chip.

FIG. 15 exemplarily illustrates a graphical representation of return loss performance of the 20 decibel attenuator chip with an operating frequency of 20 gigahertz.

FIG. 16 exemplarily illustrates a graphical representation of attenuation performance of the 20 decibel attenuator chip with an operating frequency of 20 gigahertz.

FIG. 17A exemplarily illustrates a front, top perspective view of a 30 decibel attenuator chip with an operating frequency of 20 gigahertz.

FIG. 17B exemplarily illustrates a top plan view of the 30 decibel attenuator chip with an operating frequency of 20 gigahertz.

FIG. 17C exemplarily illustrates a top plan view of the 30 decibel attenuator chip with an operating frequency of 20 gigahertz, showing an air gap in the 30 decibel attenuator chip.

FIG. 18 exemplarily illustrates a graphical representation of return loss performance of the 30 decibel attenuator chip with an operating frequency of 20 gigahertz.

FIG. 19 exemplarily illustrates a graphical representation of attenuation performance of the 30 decibel attenuator chip with an operating frequency of 20 gigahertz.

FIG. 20A exemplarily illustrates a front, top perspective view of a 20 decibel attenuator chip with an operating frequency of 30 gigahertz.

FIG. 20B exemplarily illustrates a top plan view of the 20 decibel attenuator chip with an operating frequency of 30 gigahertz.

FIG. 20C exemplarily illustrates a top plan view of the 20 decibel attenuator chip with an operating frequency of 30 gigahertz, showing an air gap in the 20 decibel attenuator chip.

FIG. 21 exemplarily illustrates a graphical representation of return loss performance of the 20 decibel attenuator chip with an operating frequency of 30 gigahertz.

FIG. 22 exemplarily illustrates a graphical representation of attenuation performance of the 20 decibel attenuator chip with an operating frequency of 30 gigahertz.

FIG. 23A exemplarily illustrates a front, top perspective view of a 30 decibel attenuator chip with an operating frequency of 30 gigahertz.

FIG. 23B exemplarily illustrates a top plan view of the 30 decibel attenuator chip with an operating frequency of 30 gigahertz.

FIG. 23C exemplarily illustrates a top plan view of the 30 decibel attenuator chip with an operating frequency of 30 gigahertz, showing an air gap in the 30 decibel attenuator chip.

FIG. 24 exemplarily illustrates a graphical representation of return loss performance of the 30 decibel attenuator chip with an operating frequency of 30 gigahertz.

FIG. 25 exemplarily illustrates a graphical representation of attenuation performance of the 30 decibel attenuator chip with an operating frequency of 30 gigahertz.

FIG. 26A exemplarily illustrates a front, top perspective view of a 20 decibel attenuator chip with an operating frequency of 40 gigahertz.

FIG. 26B exemplarily illustrates a top plan view of the 20 decibel attenuator chip with an operating frequency of 40 gigahertz.

FIG. 26C exemplarily illustrates a top plan view of the 20 decibel attenuator chip with an operating frequency of 40 gigahertz, showing an air gap in the 20 decibel attenuator chip.

FIG. 27 exemplarily illustrates a graphical representation of return loss performance of the 20 decibel attenuator chip with an operating frequency of 40 gigahertz.

FIG. 28 exemplarily illustrates a graphical representation of attenuation performance of the 20 decibel attenuator chip with an operating frequency of 40 gigahertz.

FIG. 29A exemplarily illustrates a front, top perspective view of a 30 decibel attenuator chip with an operating frequency of 40 gigahertz.

FIG. 29B exemplarily illustrates a top plan view of the 30 decibel attenuator chip with an operating frequency of 40 gigahertz.

FIG. 29C exemplarily illustrates a top plan view of the 30 decibel attenuator chip with an operating frequency of 40 gigahertz, showing an air gap in the 30 decibel attenuator chip.

FIG. 30 exemplarily illustrates a graphical representation of return loss performance of the 30 decibel attenuator chip with an operating frequency of 40 gigahertz.

FIG. 31 exemplarily illustrates a graphical representation of attenuation performance of the 30 decibel attenuator chip with an operating frequency of 40 gigahertz.

FIG. 32A exemplarily illustrates a front, top perspective view of a power divider unit.

FIG. 32B exemplarily illustrates a rear, top perspective view of the power divider unit.

FIG. 33A exemplarily illustrates a top perspective view of the power divider unit, showing the electronic circuitry of the power divider unit.

FIG. 33B exemplarily illustrates an enlarged view of a portion marked “A” of the power divider unit shown in FIG. 33A.

FIG. 33C exemplarily illustrates a top plan view of the power divider unit, showing the electronic circuitry of the power divider unit.

FIGS. 33D-33E exemplarily illustrate top plan views of a power divider unit, showing electronic circuitry of the power divider unit and air gaps of different widths in the power divider unit as an example of adjusting power dissipation and performance of the power divider unit.

FIG. 33F exemplarily illustrates a top plan view of a power divider unit, showing electronic circuitry of the power divider unit and different placements of multiple air gaps in the power divider unit.

FIG. 34 exemplarily illustrates a graphical representation of return losses of a power divider unit over a frequency range.

FIG. 35 exemplarily illustrates a graphical representation of insertion loss performance of a power divider unit over a frequency range.

FIG. 36 exemplarily illustrates a graphical representation of isolation performance of a power divider unit over a frequency range.

FIG. 37 exemplarily illustrates a top perspective view of a 20 decibel directional coupler unit.

FIG. 38A exemplarily illustrates a top perspective view of a 20 decibel directional coupler unit, showing the electronic circuitry of the 20 decibel directional coupler unit.

FIG. 38B exemplarily illustrates an enlarged view of a portion marked “B” of the 20 decibel directional coupler unit shown in FIG. 38A.

FIG. 38C exemplarily illustrates a top plan view of the 20 decibel directional coupler unit, showing the electronic circuitry of the 20 decibel directional coupler unit.

FIG. 38D exemplarily illustrates a top plan view of the 20 decibel directional coupler unit, showing the electronic circuitry of the 20 decibel directional coupler unit and an air gap in the 20 decibel directional coupler unit.

FIG. 39 exemplarily illustrates a graphical representation of return losses of the 20 decibel directional coupler unit over a frequency range.

FIG. 40 exemplarily illustrates a graphical representation of coupling performance of the 20 decibel directional coupler unit over a frequency range.

FIG. 41 exemplarily illustrates a graphical representation of isolation performance of the 20 decibel directional coupler unit over a frequency range.

### DETAILED DESCRIPTION OF THE INVENTION

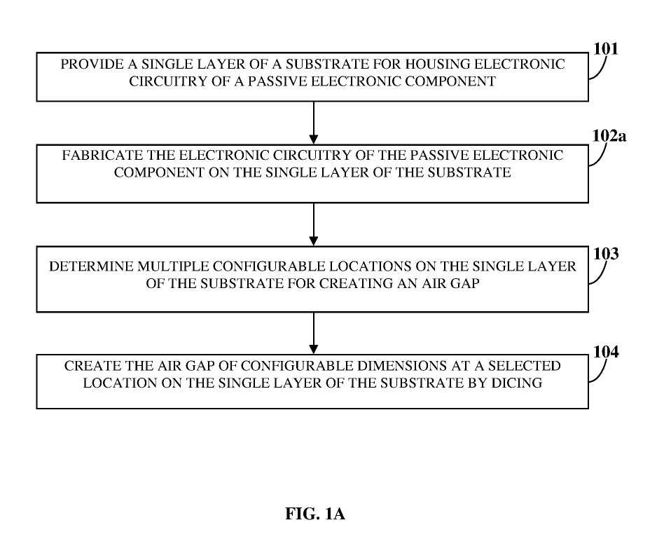

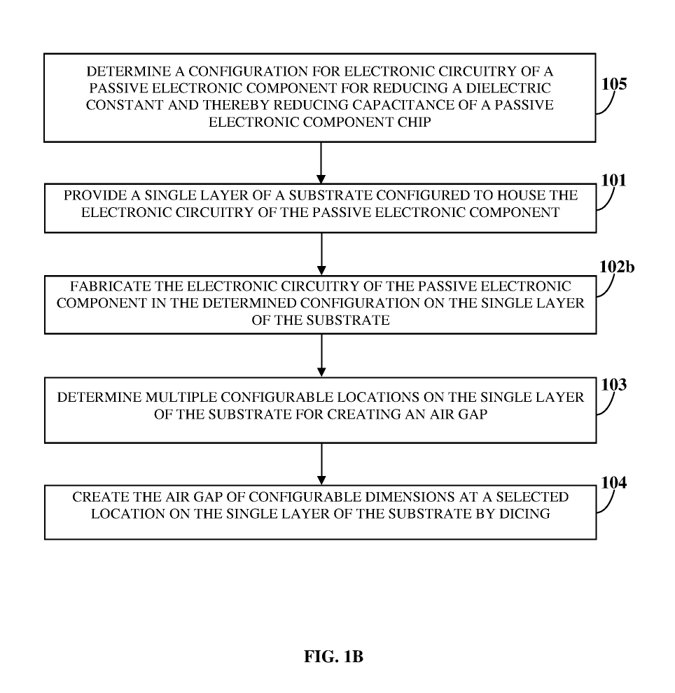

FIG. 1A illustrates a method for creating an air gap in a passive electronic component chip configured for high frequency microwave transmission. As used herein, “air gap” refers to a space, or a notch, or a groove containing air or a vacuum in a passive electronic component chip. The method disclosed herein relates to manufacturing high power, high frequency, and wide bandwidth passive electronic component products in a chip form that can operate at 50 gigahertz (GHz) and, in an embodiment, above 50 GHz. For example, the method disclosed herein configures resistors in a chip package. An air gap introduced in a substrate of a resistor reduces capacitance of the resistor, thereby making the resistor suitable for operation at high frequencies. In an embodiment, the passive electronic component chips can be standalone chips comprising, for example, one or more input ports and output ports, leads, connector tabs, etc. In another embodiment, the passive electronic component chips can be surface-mount chips that can operate without a housing. In another embodiment, the passive electronic component chips can be inserted into a coaxial housing, for example, a subminiature version A (SMA) connector housing, a 2.92 millimeter (mm) housing, a 2.4 mm housing, a 1.85 mm housing, etc., in order to form SMA terminations or attenuators, for example, 2.92 mm terminations or attenuators, 2.4 mm terminations or attenuators, 1.85 mm terminations or attenuators, etc. In other passive electronic component products, for example, directional couplers, power dividers, filters, etc., the passive electronic component units can be standalone and perform without a housing, or the passive electronic component units can be inserted into a connectorized housing. The connectorized housing is a metallic structure that can contain a substrate which can have one, two or more connectors depending on electronic circuitry components that are configured on the substrate. In the method disclosed herein, an air gap is introduced in specific areas in the substrate to create a suspended substrate-like environment. As used herein, “suspended substrate” is a substrate that is raised so that the substrate is surrounded by air by placing the substrate in a metallic enclosure to create an air layer between the substrate and the ground. By using the method disclosed herein, a design engineer can keep up with continuous technological demands of the fabrication industry, while increasing performance requirements of passive electronic components.

In the method disclosed herein, a single layer of a substrate is provided 101 for housing electronic circuitry of a passive electronic component. The substrate is, for example, a ceramic substrate. The substrate is made of ceramic material, for example, alumina, beryllium oxide (BeO), aluminum nitride (AlN), etc. The passive electronic component is, for example, a termination, an attenuator, a power divider, a resistor, a directional coupler, a hybrid coupler, a filter, etc. As used herein, the term “termination” refers to an electronic component that is provided at an end of, for example, a wire, a cable, a transmission line, a daisy chain bus such as a small computer system interface (SCSI), etc., to prevent a radio frequency (RF) signal from being reflected back from the end. A termination is configured to match impedance and hence minimize signal reflections and interference. Also, as used herein, the term “attenuator” refers to an electronic device or component that reduces power of a signal without substantially distorting a waveform of the signal.

Also, as used herein, “power divider” refers to an electronic device or component that divides input power into smaller amounts of power. A power divider comprises an input port and two or more output ports. An input signal at an input port of a power divider is split between the output ports depending on the specifications of a design of the electronic circuitry of the power divider, or is split equally between two or more output ports of the power divider. Also, as used herein, “directional coupler” refers to an electronic device or component that couples a defined amount of electromagnetic power in a transmission line to a port enabling a signal to be used in another circuit. A directional coupler comprises an input port, an output port, a coupled port, and an isolated port. A directional coupler couples power flowing in only one direction. For example, power entering an input port of the directional coupler is coupled to a coupled port but not to an isolated port of the directional coupler. Also, as used herein, the term “filter” refers to an electronic component configured in an analog circuit to perform signal processing functions, specifically to remove unwanted frequency components from a signal and/or enhance wanted frequency components. A “resistor” refers to a passive two-terminal electrical component that implements electrical resistance as a circuit element. As used herein, “hybrid coupler” refers to a passive electronic component used in the field of radio and telecommunications. A hybrid coupler is a type of a directional coupler where input power is divided equally between two output ports.

The electronic circuitry of the passive electronic component is fabricated 102a, for example, on an upper section of the substrate to create the passive electronic component chip. In an embodiment, one or more vias are configured in the single layer of the substrate of the passive electronic component chip. As used herein, the term “vias” refers to an electronic connection between layers in electronic circuitry that passes through a plane of one or more adjacent layers. The vias are configured to increase power dissipation of the passive electronic component chip by allowing a ground connection of the electronic circuitry of the passive electronic component from an upper section of the passive electronic component chip to a metalized lower section of the passive electronic component chip through the vias. For example, a solid ground connection from the top surface to the metalized bottom surface of the passive electronic component chip is connected through the vias configured in the substrate. In an embodiment, the passive electronic component chip obtains a ground connection horizontally by touching or connecting a metal electrode from the top surface of the passive electronic component chip to a housing.

In an embodiment, multiple configurable locations, for example, on a lower section of the substrate are determined 103 for creating the air gap. In an embodiment, the air gap is created by dicing the substrate along a dicing path determined for creating the air gap in the lower section of the substrate of the passive electronic component chip. For example, a design engineer determines a dicing path of configurable dimensions on a lower section of the substrate for creating the air gap to attain a reduced dielectric constant in the dicing path for high frequency microwave transmission. A design engineer selects one or more of the determined configurable locations for creating the air gap. The design engineer selects areas on the lower section of the substrate that have more capacitive effect to insert the air gap.

An air gap of configurable dimensions is then created 104 at the selected location, for example, on the lower section of the substrate by dicing the substrate at the selected location using a dicing blade. The dimensions of the air gap are determined for different passive electronic components based on the frequency and the power required for the design of the electronic circuitry of the passive electronic component chip. In an embodiment, the dimensions such as width, length, and depth of the air gap can vary depending on the power, frequency, and electrical specifications. A generally rectangular slot is cut in a selected location on the substrate for creating the air gap. A slot that defines the air gap can be cut to a width, for example, between about 10 mils to about 2000 mils, where one mils is equal to 0.001 inches. For example, in an embodiment, a slot that defines the air gap for a termination chip operating at 20 GHz can be cut to a width of 12 mils, 13 mils, or 20 mils. In another example, a slot that defines the air gap for a termination chip operating at 30 GHz or 40 GHz can be cut to a width of 20 mils. In another example, a slot that defines the air gap for a termination chip operating at 50 GHz can be cut to a width of 23 mils. In another example, a slot that defines the air gap for an attenuator chip operating at 20 GHz, 30 GHz, or 40 GHz can be cut to a width of 20 mils. In another example, the a slot that defines air gap for a power divider unit can be cut to a width of 700 mils, 36 mils, or 20 mils. In another example, a slot that defines the air gap for a directional coupler unit can be cut to a width of 1720 mils.

A slot that defines the air gap can be cut to a length of, for example, between about 2 mils to about 15 mils. For example, in an embodiment, a slot that defines the air gap for a termination chip operating at 20 GHz, 30 GHz, or 40 GHz can be cut to a length of 5 mils. In another example, a slot that defines the air gap for a termination chip operating at 50 GHz can be cut to a length of 10 mils. In another example, a slot that defines the air gap for an attenuator chip operating at 20 GHz, 30 GHz, or 40 GHz can be cut to a length of 5 mils. In another example, a slot that defines the air gap for a power divider unit can be cut to a length of 10 mils. In another example, a slot that defines the air gap for a 20 dB directional coupler unit can be cut to a length of 5 mils. Furthermore, a slot that defines the air gap can be cut to a depth of, for example, between about 80 mils to about 3000 mils. For example, in an embodiment, a slot that defines the air gap for a termination chip operating at 20 GHz, 30 GHz, 40 GHz, or 50 GHz can be cut to a depth of 100 mils. In another example, a slot that defines the air gap for an attenuator chip operating at 20 GHz or 30 GHz can be cut to a depth of 100 mils. In another example, a slot that defines the air gap for an attenuator chip operating at 40 GHz can be cut to a depth of 90 mils. In another example, a slot that defines the air gap for a power divider unit can be cut to a depth, for example, between 700 mils and 2800 mils, for example, cut to a depth of 2370 mils. In another example, a slot that defines the air gap for a 20 dB directional coupler unit can be cut to a depth of 560 mils.

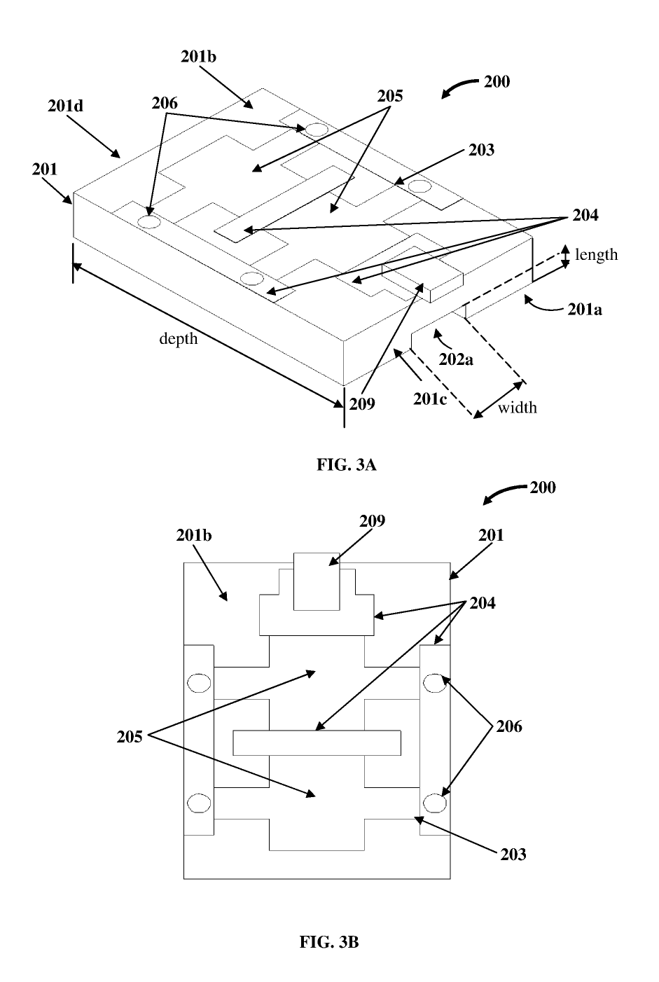

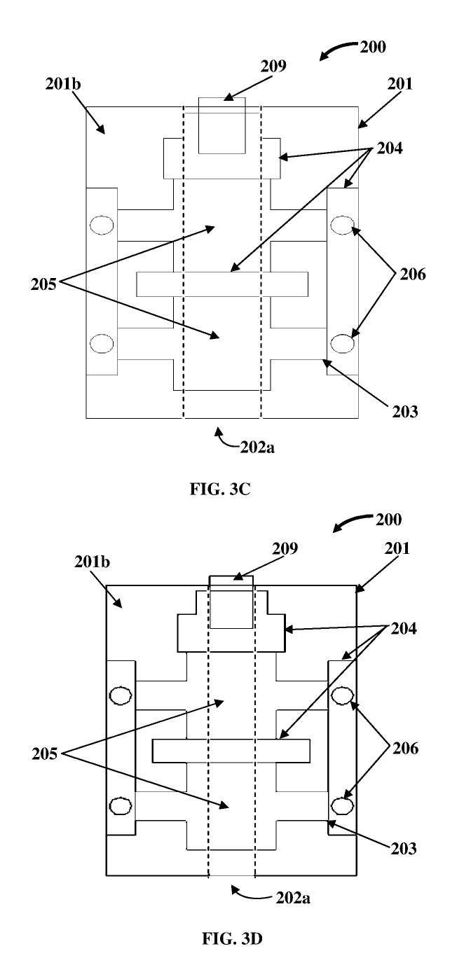

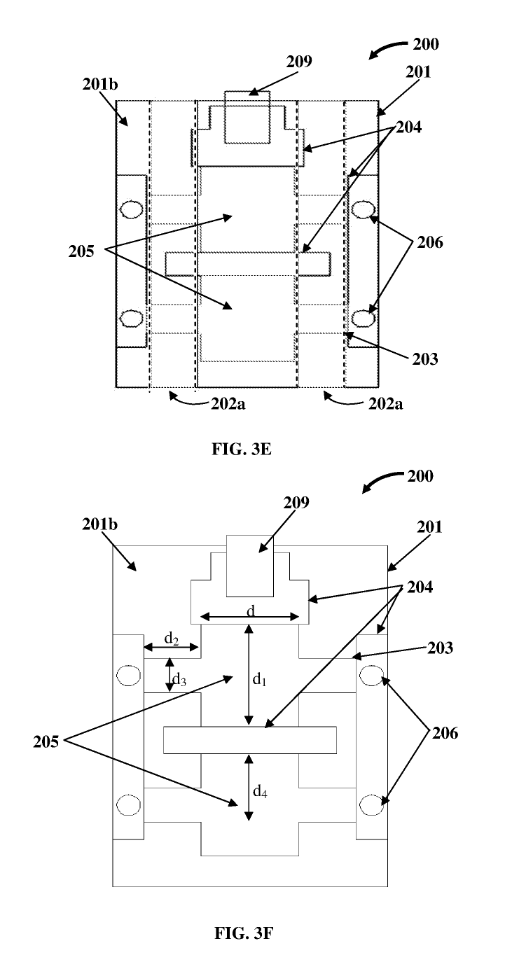

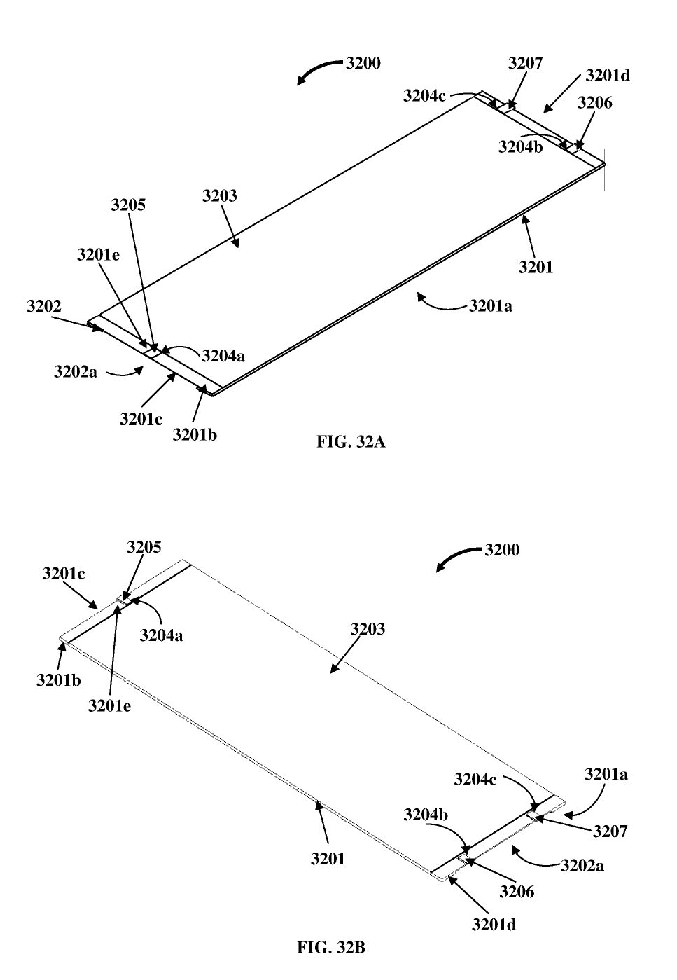

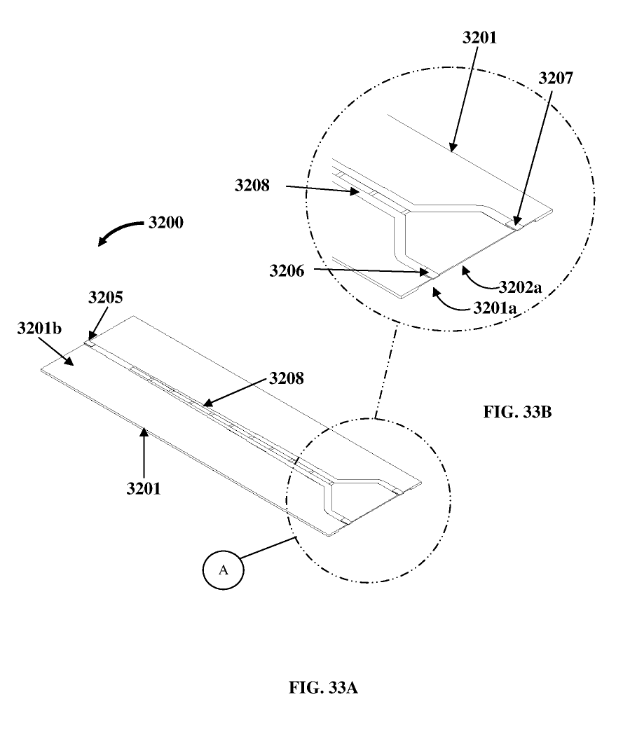

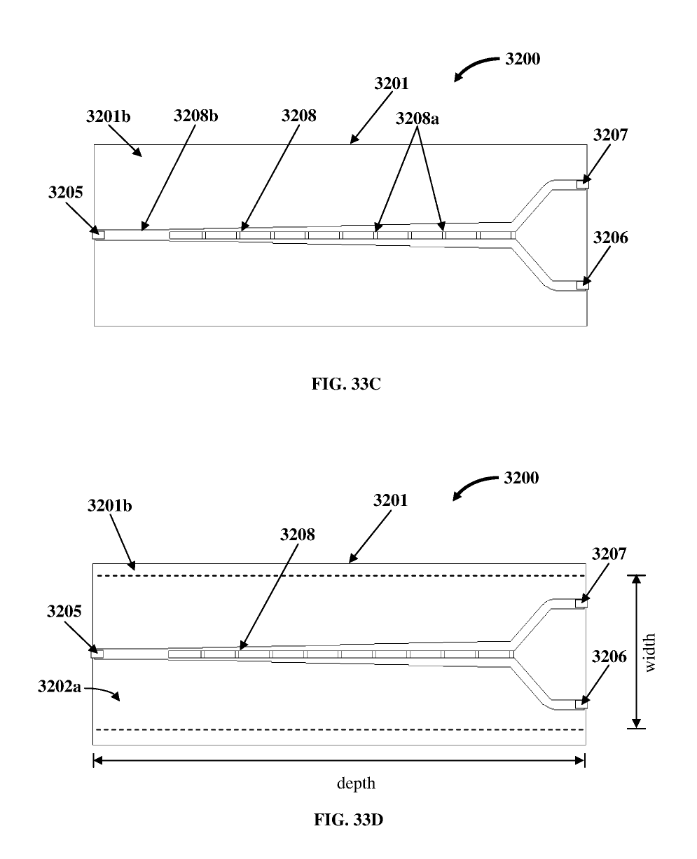

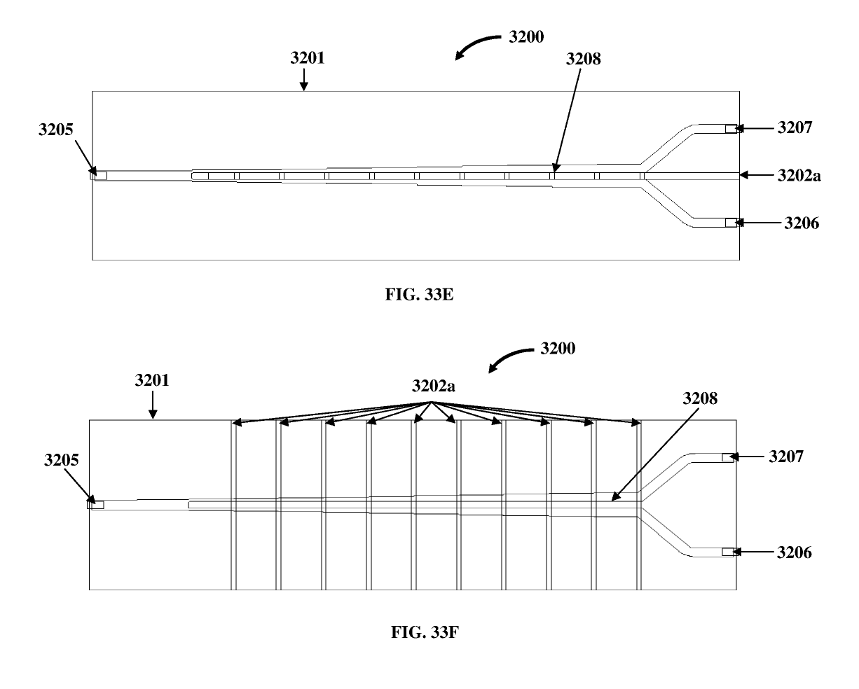

A design engineer can search for high capacitance sections, herein referred to as “resistive regions”, and introduce an air gap below the identified resistive regions. In an embodiment, one or more additional air gaps of multiple configurable dimensions can be created at one or more of the determined configurable locations on the single layer of the substrate by dicing the single layer of the substrate at the selected locations. The additional air gaps are configured to adjust power dissipation and performance of the passive electronic component chip. A design engineer determines, for example, a width, a length, a depth, etc., of the air gap based on the frequency and the power required for the design of the electronic circuitry of the passive electronic component chip. The design engineer can adjust the width of the air gap to vary the power dissipation. For example, the width of the air gap can be adjusted, for example, between about 10 mils and about 2000 mils. In an embodiment, the width of the air gap can be adjusted between about 5 mils to about 20 mils, for example, about 10 mils. In an embodiment, the depth of the air gap is equal to the depth of the substrate. In another embodiment, the depth of the air gap is less than the depth of the substrate. The design engineer can also select multiple different locations on the substrate for positioning one or more additional air gaps for increasing power dissipation of the passive electronic component chip. The air gaps can also be oriented in different directions, for example, along the length of the substrate or along the width of the substrate as exemplarily illustrated in FIGS. 33E-33F. The air gap is configured to create a suspended substrate-like environment in the passive electronic component chip. The air gap is further configured to attain a reduced dielectric constant at the selected location for high frequency microwave transmission. That is, the effective dielectric constant in the selected location is lower than that of the remaining portion of the substrate. Multiple air gaps of different dimensions can be inserted on a single substrate as exemplarily illustrated in FIG. 3E and FIG. 33F.

The method disclosed herein introduces an air gap in a single layer of a substrate in selected locations or areas of the single layer of the substrate by creating a slot or a cut, hereinafter referred to as a cut, in the substrate using a dicing mechanism. The dicing mechanism comprises, for example, a dicing machine, a dicing blade, laser technology, etc. A cut is made at a configurable location in the substrate of the passive electronic component chip using the dicing mechanism. For example, by using a dicing blade with a single or a series of overlapping cuts, a slot of a predetermined depth is created at a selected location in the substrate to create an air gap and obtain a predetermined dielectric constant for the passive electronic component chip. An effective dielectric constant in the selected location or area of the substrate where the air gap is introduced is lower than the dielectric constant of a remaining portion of the substrate. Hence, the method disclosed herein creates a passive electronic component chip with a selected location of the substrate having a lower dielectric constant than the actual dielectric constant of the substrate. That is, the passive electronic component chip will have a different effective dielectric constant based on the location of the air gap on the substrate of the passive electronic component chip. For purposes of illustration, the detailed description refers to a method of cutting or dicing the substrate using a dicing blade for making a cut or a slot in the substrate for creating the air gap; however the scope of the method disclosed herein is not limited to a dicing method but may be extended to include other cutting or functionally equivalent methods for creating the air gap in the substrate.

The created air gap in the passive electronic component chip reduces the capacitance of the substrate along areas located directly above the air gap, along with a reduction in loss tangent (tans), high frequency attenuation, and electromagnetic fields near a ground plane of the passive electronic component chip. Furthermore, the air gap creates a wider strip dimension and less stringent tolerance. As used herein, “loss tangent” refers to a parameter for defining dielectric loss of a dielectric material. Also, as used herein, “dielectric loss” refers to a quantified value of inherent dissipation of electromagnetic energy of a dielectric material into another form of energy, for example, heat energy. The dielectric constant of air is approximately 1 and the loss tangent of air is zero. Hence, by introducing an air gap at a selected location of the substrate, the effective dielectric constant of the substrate material is reduced as a result of the dielectric constant of the air gap. Therefore, by reducing the dielectric constant of the substrate material, the loss tangent of the substrate material is also reduced. The air gap reduces the dielectric loss and conductor loss of the substrate material, thereby reducing high frequency attenuation of the substrate.

Furthermore, by reducing field near ground plane, the air gap reduces conductor loss of the passive electronic component chip. A substantial part of an electromagnetic field is confined in the air gap between the substrate and the ground plane. Hence, by introducing an air gap in the substrate, the electromagnetic fields near the ground plane of the passive electronic component chip are reduced. Furthermore, when reducing the effective dielectric constant of a substrate material by the creation of the air gap, a wider transmission line is required in the substrate. A wider transmission line is required to maintain the same characteristic impedance of the transmission line as when there was no air gap. An air gap introduced in a substrate of a passive electronic component chip reduces the effective dielectric constant and the capacitance of the substrate. With the reduced effective dielectric constant and the reduced capacitance of the substrate, a design engineer needs to accommodate new parameters for a wider strip dimension in the design of the passive electronic component chip. First, an air gap is created in the substrate and then the transmission line is designed to accommodate the air gap with the reduced effective dielectric constant. In a low dielectric constant material, a wider transmission line is required to obtain the same characteristic impedance as compared to a high dielectric constant material. For example, a 50 ohms (Ω) transmission line will be wider in a low dielectric constant material than a high dielectric constant material due to capacitance differences. Hence, the creation of an air gap in the substrate of a passive electronic component chip results in a wider strip dimension of the substrate of the passive electronic component chip.

The positioning and/or dimensions of an air gap introduced in a substrate of a passive electronic component chip create a less stringent tolerance for the passive electronic component chip. The air gap causes transmission lines, also referred to as “conductors”, and resistive regions of the electronic circuitry of the passive electronic component chip to be wider because of the reduction in the dielectric constant of the substrate, thereby resulting in wider strip dimensions of the substrate. When designs for the electronic circuitry of a passive electronic component chip are built, the inaccuracies, herein referred to as “tolerance” of electronic circuitry dimensions are smaller because of the wider strip dimensions. That is, building a passive electronic component chip with wider strip dimensions is easier than building a passive electronic component chip with narrower strip dimensions, particularly for building passive electronic component chips operating at high frequencies. Moreover, the tolerance of passive electronic component chips operating at high frequencies is optimal when the passive electronic component chips have wider strip dimensions.

In an embodiment, the passive electronic component chip is configured, for example, as a surface-mount passive electronic component chip, or a standalone passive electronic component chip comprising one or more connector tabs, or a passive electronic component chip enclosed in a coaxial housing, or a passive electronic component chip enclosed in a connectorized housing. After the design of the electronic circuitry of a passive electronic component is fabricated, for example, on the upper section of the ceramic substrate, a layer of epoxy is screen printed on the upper section of the ceramic substrate, except on the locations of input ports and output ports of the passive electronic component chip. In various embodiments, the upper section of the substrate of the passive electronic component chip is covered with a layer of epoxy, except in the locations of the input ports and the output ports where the connector tabs are positioned, to protect the passive electronic component chip from an external environment. The input ports and the output ports house the connector tabs of the passive electronic component chip or enable the passive electronic component chip to be inserted into a coaxial housing to attach to a pin of each of one or more coaxial connectors, for example, subminiature version A (SMA) connectors, 2.92 mm connectors, 2.4 mm connectors, 1.85 mm connectors, etc. The connector tabs can protrude through the input ports and the output ports.

FIG. 1B illustrates an embodiment of the method for creating an air gap in a passive electronic component chip configured for high frequency microwave transmission. In this embodiment, a configuration for electronic circuitry of a passive electronic component, for example, a termination, an attenuator, etc., is determined 105 for reducing a dielectric constant and thereby reducing capacitance of the passive electronic component chip. Furthermore, in this embodiment, the reduction of power dissipation resulting from the removal of the substrate material is compensated by integrating a solid connection through vias to a large surface area of the ground of the passive electronic component chip. In an example, the configuration of the electronic circuitry of a termination and an attenuator with an air gap in a substrate of each of the termination chip and the attenuator chip that can operate, for example, from direct current (DC) to 20 GHz, DC to 30 GHz, DC to 40 GHz, and DC to 50 GHz are determined. Based on the frequencies and the power dissipation in the electronic circuitry configuration, two resistive regions are cascaded to improve the performance. The width and the length of these resistive regions are adjusted to obtain improved electrical performance. Adjustments of the width and the length are based on the frequencies. For example, when configuring a 40 GHz passive electronic component chip, the surface areas of the resistive regions are less than the surface areas of the resistive regions of a 30 GHz passive electronic component chip since the wavelength of the frequency at 40 GHz is less than the wavelength of the frequency at 30 GHz, at 20 GHz, and so on. Fabrication technologies, for example, thin film technology, thick film technology, low temperature co-fired ceramic (LTCC) technology, high temperature co-fired ceramic (HTCC) technology, etc., are used to design and fabricate a variety of high power, high frequency, and wide bandwidth products, for example, power dividers, directional couplers, hybrid couplers, filters, etc., on the substrate of a passive electronic component chip.

After determination of the electronic circuitry, the method disclosed herein proceeds with steps 101, 103, and 104 as disclosed in the detailed description of FIG. 1A. After providing 101 a single layer of a substrate, the electronic circuitry of the passive electronic component is fabricated 102b, for example, on an upper section of the substrate in the determined configuration. In an embodiment, the design of the electronic circuitry is coated on a surface of a ceramic substrate. After determination 103 of a location for the air gap, the air gap of configurable dimensions is created 104 at the determined location, for example, on the lower section of the substrate by employing a dicing mechanism as disclosed in the detailed description of FIG. 1A. The air gap is configured at one of the determined configurable locations to attain a reduced dielectric constant at the determined configurable location for high frequency microwave transmission.

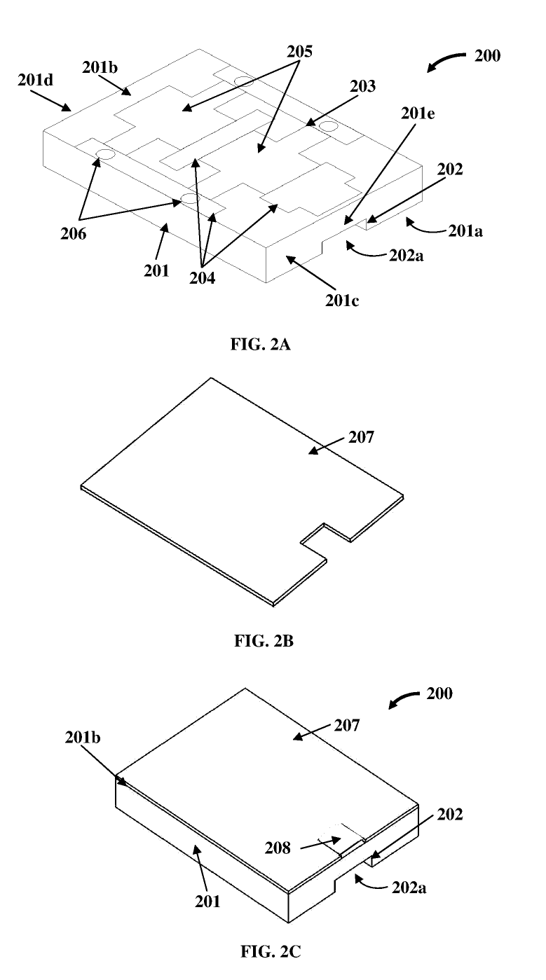

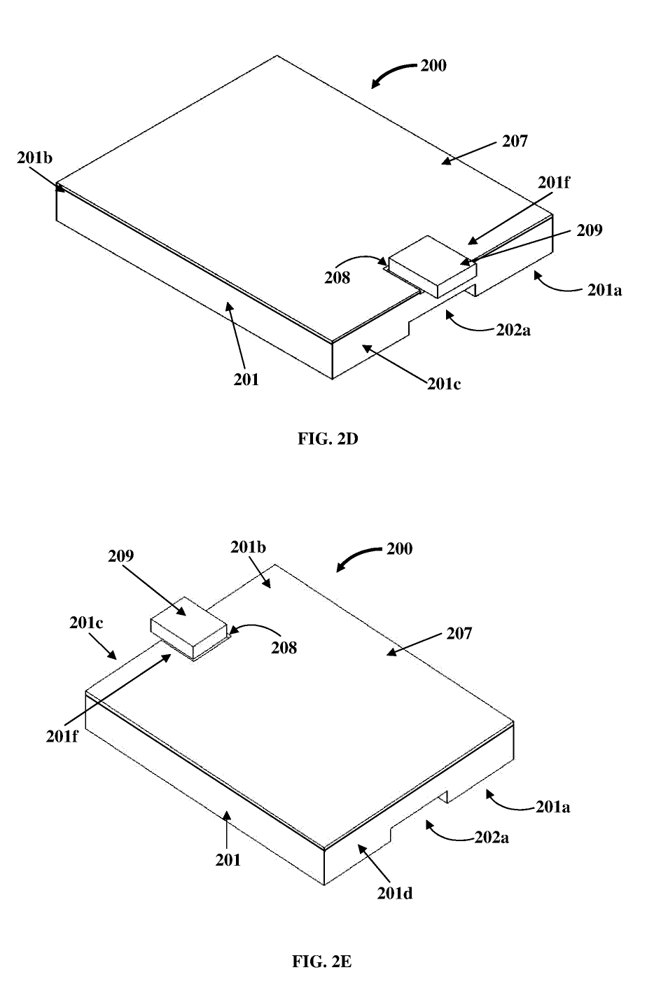

FIG. 2A exemplarily illustrates a front, top perspective view showing electronic circuitry 203 of a termination fabricated on an upper section 201b of a substrate 201 of a termination chip 200. In an embodiment, the termination chip 200 can be a standalone chip or the substrate 201 of the termination chip 200 can be inserted into a coaxial housing (not shown). FIG. 2A exemplarily illustrates components of the electronic circuitry 203 of the termination chip 200. The electronic circuitry 203 of the termination chip 200 comprises, for example, electrodes 204 made of high conductivity metals, resistive regions 205 having resistance networks, and vias 206 for a ground plane connection. An air gap 202a is created in the substrate 201 of the termination chip 200. As exemplarily illustrated in FIG. 2A, the air gap 202a is created in a lower section 201a of the substrate 201 using a dicing mechanism. For example, a generally rectangular slot 202 is made in the lower section 201a of the substrate 201 by removing a portion of the substrate 201 from the lower section 201a of the substrate 201 using a dicing blade for creating the air gap 202a. The slot 202 is positioned approximately at a mid-section 201e of the substrate 201. The slot 202 that defines the air gap 202a extends from one end 201c of the substrate 201 to the other end 201d of the substrate 201.

FIG. 2B exemplarily illustrates a layer of epoxy 207 configured to be screen printed on the upper section 201b of the substrate 201 of the termination chip 200. The layer of epoxy 207 is used to cover the upper section 201b of the substrate 201 exemplarily illustrated in FIG. 2A, after the termination chip 200 has been configured. The layer of epoxy 207 is added to protect the termination chip 200 from an external environment.

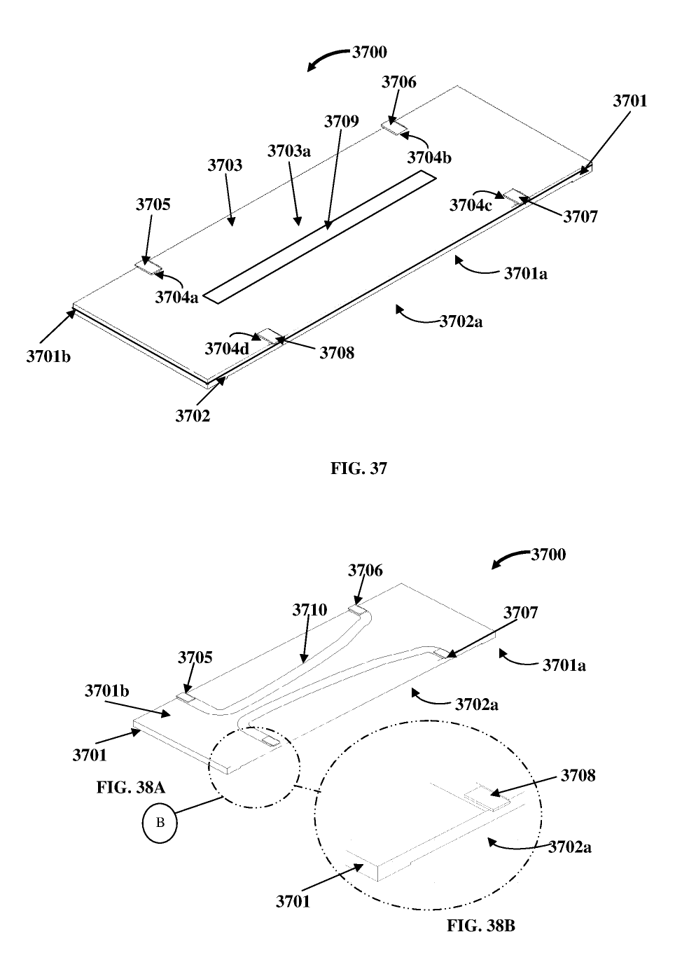

FIG. 2C exemplarily illustrates a front, top perspective view of the termination chip 200, showing the layer of epoxy 207 screen printed on the upper section 201b of the substrate 201 of the termination chip 200. After the design or configuration of the electronic circuitry 203 of the termination chip 200 is fabricated on the upper section 201b of the substrate 201 exemplarily illustrated in FIG. 2A, a layer of epoxy 207 is screen printed on the upper section 201b of the substrate 201 to protect the termination chip 200 from an external environment. An input port 208 positioned on the upper section 201b of the substrate 201 is configured to house an input connector tab 209 exemplarily illustrated in FIGS. 2D-2E, or to attach to a pin of a coaxial connector (not shown). The input connector tab 209 is either attached to the input port 208, or the input port 208 is left free if the termination chip 200 is to be inserted into a coaxial housing (not shown) to allow the input port 208 to be attached to a coaxial connector. The above steps of fabricating the termination chip 200 are also used for fabricating an attenuator chip 1200 exemplarily illustrated in FIGS. 12A-12B, a power divider unit 3200 exemplarily illustrated in FIGS. 32A-32B, a directional coupler unit 3700 exemplarily illustrated in FIG. 37, and other electronic components and devices.

FIGS. 2D-2E exemplarily illustrate perspective views of the termination chip 200, showing an input connector tab 209 and an air gap 202a configured in the substrate 201 of the termination chip 200. FIG. 2D exemplarily illustrates a front, top perspective view of the termination chip 200. FIG. 2E exemplarily illustrates a rear, top perspective view of the termination chip 200. The input connector tab 209 is positioned approximately at a mid position 201f of an upper section 201b of the substrate 201 at one end 201c of the substrate 201. In an embodiment, the input connector tab 209 is attached to the input port 208 of the termination chip 200, or the input port 208 is left unattached if the termination chip 200 is to be inserted into a coaxial housing (not shown), so that the input port 208 can be attached to a pin of a coaxial connector (not shown).

FIGS. 3A-3C exemplarily illustrate different views of a termination chip 200 with an operating frequency of 20 GHz, showing components of the electronic circuitry 203 of the termination chip 200. The electronic circuitry 203 of the termination chip 200 is fabricated on the upper section 201b of the substrate 201. FIG. 3A exemplarily illustrates a front, top perspective view of the termination chip 200, showing the components of the electronic circuitry 203 of the termination chip 200. FIG. 3A also exemplarily illustrates the air gap 202a created in the lower section 201a of the substrate 201 of the termination chip 200. The dimensions of the air gap 202a are, for example, width, length, and depth of the air gap 202a. FIG. 3B exemplarily illustrates a top plan view of the termination chip 200, showing the components of the electronic circuitry 203 of the termination chip 200. FIG. 3C exemplarily illustrates a top plan view of the termination chip 200 with an operating frequency of 20 GHz, showing the components of the electronic circuitry 203 of the termination chip 200 and an air gap 202a in hidden lines in the termination chip 200. The layer of epoxy 207 exemplarily illustrated in FIG. 2B, is not shown in FIGS. 3A-3C.

In an embodiment, the termination chip 200 can be a standalone unit, or the termination chip 200 can be inserted into a coaxial housing (not shown). If the termination chip 200 is inserted into a coaxial housing, the power performance of the termination chip 200 is improved when compared with conventional or standard coaxial terminations because of the direct connection to a solid ground plane of the termination chip 200. A termination chip 200 packaged in a coaxial housing is robust and cheaper to build compared to conventional coaxial terminations.

FIGS. 3D-3E exemplarily illustrate top plan views of the termination chip 200 with an operating frequency of 20 GHz, showing the components of the electronic circuitry 203 of the termination chip 200 and one or more air gaps 202a of dimensions different from the dimensions of the air gap 202a exemplarily illustrated in FIG. 3C, for adjusting the power dissipation of the termination chip 200. FIG. 3C exemplarily illustrates an air gap 202a of a relatively larger dimension in the termination chip 200 as compared to the air gap 202a in the termination chip 200 exemplarily illustrated in FIG. 3D. For example, dimensions of the air gap 202a of the termination chip 200 exemplarily illustrated in FIG. 3C are width=20.0 mils; length=5.0 mils; and depth=100.0 mils, whereas dimensions of the air gap 202a of the termination chip 200 exemplarily illustrated in FIG. 3D are width=12.0 mils; length=5.0 mils; and depth=100.0 mils. In an embodiment, the depth of the air gap 202a is equal to the depth of the substrate 201 as exemplarily illustrated in FIGS. 3C-3D. These dimensions can be adjusted depending on the power, frequency, and electrical specifications of the termination chip 200. FIG. 3D exemplarily illustrates an example of adjusting the width of the air gap 202a for adjusting the performance and the power dissipation of the termination chip 200. In an embodiment, multiple air gaps 202a of different dimensions can be inserted into a single substrate 201. FIG. 3E exemplarily illustrates a top plan view of the termination chip 200, showing the components of the electronic circuitry 203 of the termination chip 200 and two air gaps 202a in the termination chip 200. FIG. 3E exemplarily illustrates introduction of additional air gaps 202a to adjust the performance and the power dissipation of the termination chip 200. Example dimensions of each of the two air gaps 202a of the termination chip 200 exemplarily illustrated in FIG. 3E are width=13.0 mils; length=5.0 mils; and depth=100.0 mils. These dimensions can be adjusted depending on the power, frequency, and electrical specifications of the termination chip 200. The termination chip 200 exemplarily illustrated in FIG. 3E provides another example for adjusting the width and the location of the air gap 202a to adjust the power dissipation and the performance of the termination chip 200. The width and the location of the air gaps 202a can be altered to increase the power dissipation.

FIG. 3F exemplarily illustrates a top plan view of the termination chip 200 with an operating frequency of 20 GHz, showing positioning of the components of the electronic circuitry 203 of the termination chip 200 at different distances, for example, d, d₁, d₂, d₃, and d₄.

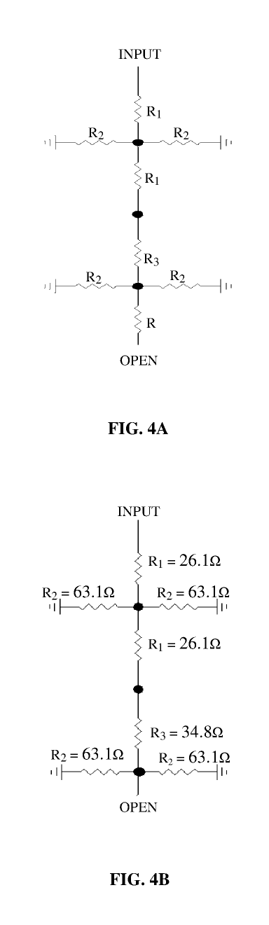

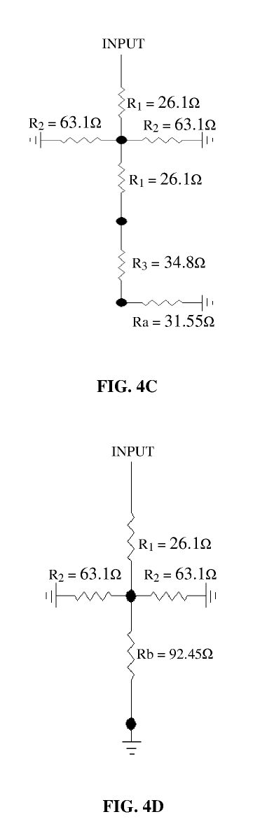

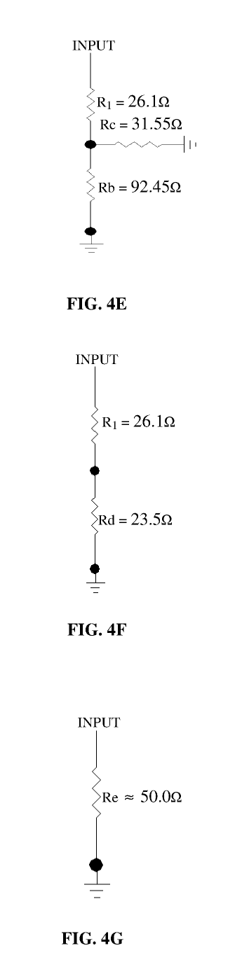

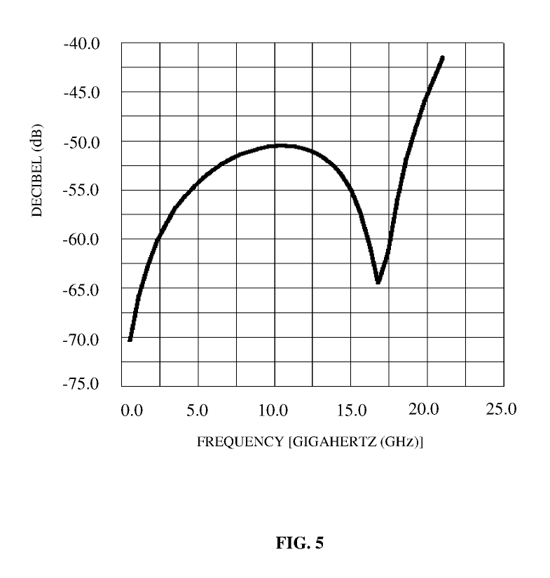

FIG. 4A exemplarily illustrates a circuit diagram corresponding to the termination chip 200 shown in FIGS. 3A-3C and FIG. 3F, showing two cascaded T-type resistance networks connected in series in the shape of a cross symbol “+”. The electronic circuitry 203 of the termination chip 200 comprises two T-type resistance networks cascaded in series. In addition to the reduction in capacitance caused by the air gap 202a in the substrate 201 of the termination chip 200 exemplarily illustrated in FIG. 2A, FIGS. 2C-2E, and FIGS. 3A-3C, the electronic circuitry 203 of the termination chip 200 further reduces the capacitance of the termination chip 200. Consider an example where the distances between the components of the electronic circuitry 203 of the termination chip 200 exemplarily illustrated in FIG. 3F are denoted by “d”, “d₁”, “d₂”, “d₃”, and “d₄”. The values of the resistors R₁, R₂, and R₃ exemplarily illustrated in FIG. 4A, are determined based on resistivity of the resistive regions 205 of the termination chip 200 exemplarily illustrated in FIGS. 3A-3C and FIG. 3F, and dimensions, for example, “d”, “d₁”, “d₂”, “d₃”, and “d₄” of the termination chip 200.

The value of the resistor R₁ is determined by dividing (d₁)/2 by the value of distance “d” and then multiplying the result with the resistivity of the resistive region 205. The value of the resistor R3 is determined by using the values of distances d and d₄, and the value of the resistivity, where d₄ is the distance from an electrode that separates the resistive regions 205 and an end edge of the resistor R₂ in a second region, as exemplarily illustrated in FIG. 3F and FIG. 4A. Consider an example where the resistivity of the resistive regions 205 is 43.5Ω2/square, and the distances between the components of the electronic circuitry 203 of the termination chip 200 are configured as d=25.0 mils, d₁=30.0 mils, d₂=14.5 mils, d₃=10.0 mils, and d₄=20.0 mils. To find the values for the resistors in the electronic circuitry 203, the equation R=(resistivity)*(number of squares) is used, where R=resistivity multiplied by the number of squares in an area of interest. To find R₁, the number of squares in the area of interest is determined. Therefore, by applying the equation: (d₁/2)/d=(15)/25=0.6 square, R₁=(43.5Ω/square)*(0.6 square)=26.1 ohms. To find R₂, the number of squares is first calculated using the equation: (d₂/d₃)=(14.5/10)=1.45 squares. Therefore, R₂=(43.5Ω/square)*(1.45 square)=approximately 63.1 ohms. To find R₃, the number of squares is first calculated using the equation: (d₄/d)=(20.0/25.0)=0.8 squares. Therefore, R₃=(43.5Ω/square)*(0.8 square)=34.8 ohms. Therefore, based on the resistivity of the resistive regions 205 of the termination chip 200 and the dimensions “d”, “d₁”, “d₂”, “d₃”, and “d₄” of the termination chip 200 exemplarily illustrated in FIG. 3F, the values of the resistors are R₁=26.1 ohms, R₂=63.1 ohms, R₃=34.8 ohms. The circuit exemplarily illustrated in FIG. 4A is an open circuit and there is no current going through the resistor R. A resultant design for a 50 ohms termination chip 200 determined using the calculated values of the resistors R₁, R₂, and R₃ is exemplarily illustrated in FIG. 3F.

FIGS. 4B-4G exemplarily illustrate circuit diagrams of equivalent circuits of the 50 ohms termination chip 200 shown in FIGS. 3A-3C and FIG. 3F, with an operating frequency of 20 GHz. FIGS. 4B-4G exemplarily illustrate the calculations of the values of the resistors R₁, R₂, and R₃ cascaded in series in two T-type resistance networks to obtain a resultant resistor Rₑ of a value of about 50 ohms. FIG. 4C exemplarily illustrates the value of an equivalent resistor Rₐ as 31.55 ohms obtained by calculating an equivalent value of two R₂ resistors connected in parallel shown in FIG. 4B. FIG. 4D exemplarily illustrates the value of an equivalent resistor R_{b} as 92.45 ohms obtained by calculating an equivalent value of the resistors Rₐ, R₁, and R₃ connected in series. FIG. 4E exemplarily illustrates the value of an equivalent resistor Rₑ as 31.55 ohms obtained by calculating an equivalent value of two R₂ resistors connected in parallel shown in FIG. 4D. FIG. 4F exemplarily illustrates the value of an equivalent resistor R_{d} as 23.5 ohms obtained by calculating an equivalent value of the resistors R_{b} and R_{c} connected in parallel shown in FIG. 4E. FIG. 4G exemplarily illustrates the value of an equivalent resistor R_{c} as approximately equal to 50 ohms obtained by calculating an equivalent value of the resistors R₁ and R_{d} connected in series shown in FIG. 4F.

The method disclosed herein can be used to design terminations that operate, for example, from DC to 20 GHz, DC to 30 GHz, DC to 40 GHz, DC to 50 GHz, etc. The power dissipation of the termination chip 200 varies, for example, from about 5 watts (W) to about 12 W. The power dissipation of the termination chip 200 can be increased based on the dimensions of the electronic circuitry 203, the dimensions and the locations of the air gap 202a, the material of the termination chip 200, and the technology used to build the design. As exemplarily illustrated in FIG. 4A, each resistive region 205 in the electronic circuitry 203 of the termination chip 200 is a T-type resistance network connected in series in the shape of a cross symbol “+”. The equivalent lumped models of the two resistive regions 205 are connected in both series and parallel connections as exemplarily illustrated in FIGS. 4A-4G. The resulting summation of the resistance values of the resistors in the two resistive regions 205 is 50 ohms. In an embodiment, three or more resistive regions 205 can be used in the electronic circuitry 203 of the termination chip 200 to increase power dissipation of the termination chip 200.

FIG. 5 exemplarily illustrates a graphical representation of return loss performance of the termination chip 200 with an operating frequency of 20 GHz exemplarily illustrated in FIG. 2A, FIGS. 2C-2E, and FIGS. 3A-3C. A simulation is performed by using a high frequency structural simulator (HFSS) to evaluate the design of the termination chip 200. FIG. 5 exemplarily illustrates the performance of the termination chip 200, which is the result of the reduction in the capacitance and the losses in the material caused by the air gap 202a and the design of the termination chip 200. The termination chip 200 with an air gap 202a at a selected location on the substrate 201 is simulated at an operating frequency of 20 GHz using the HFSS. The benefit of reducing the capacitance of the termination chip 200 with an operating frequency of 20 GHz is exemplarily illustrated in FIG. 5. The return loss obtained for the termination chip 200 operating at 20 GHz is, for example, more than about 45 dB.

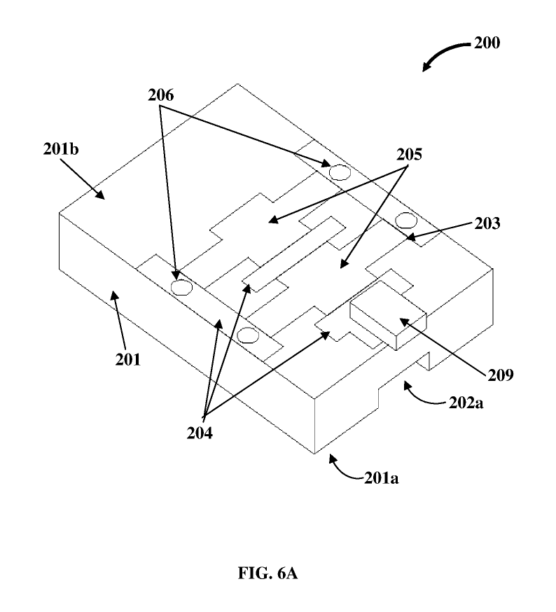

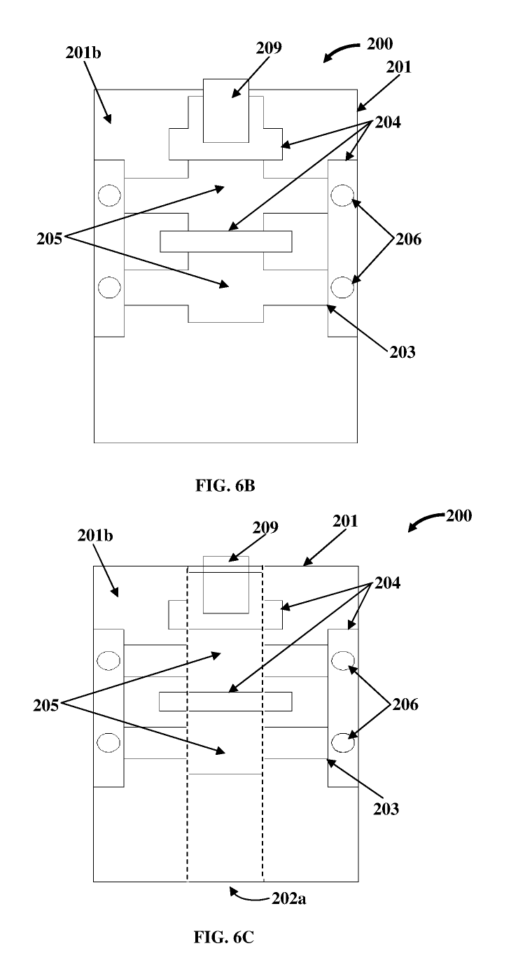

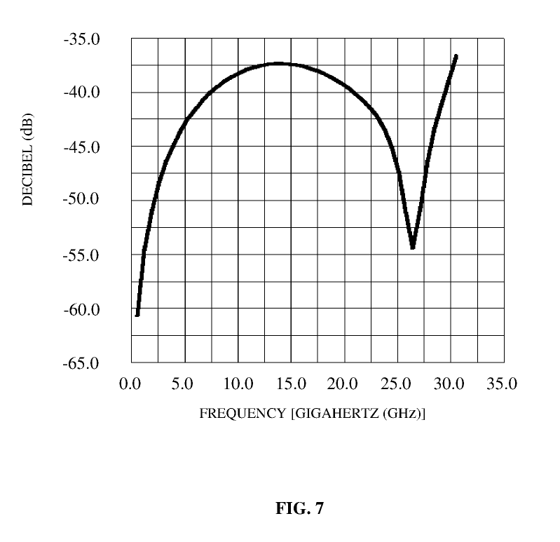

FIGS. 6A-6C exemplarily illustrate different views of a termination chip 200 with an operating frequency of 30 GHz, showing components of the electronic circuitry 203 of the termination chip 200. FIG. 6A exemplarily illustrates a front, top perspective view of the termination chip 200 with an operating frequency of 30 GHz. FIG. 6B exemplarily illustrates a top plan view of the termination chip 200 with an operating frequency of 30 GHz. FIG. 6C exemplarily illustrates a top plan view of the termination chip 200 with an operating frequency of 30 GHz, showing an air gap 202a in hidden lines in the termination chip 200. Example dimensions of the air gap 202a of the termination chip 200 exemplarily illustrated in FIG. 6C are width=20.0 mils; length=5.0 mils; and depth=100.0 mils. These dimensions can be adjusted depending on the power, frequency, and electrical specifications of the termination chip 200. The layer of epoxy 207 exemplarily illustrated in FIG. 2B, is not shown in FIGS. 6A-6C.

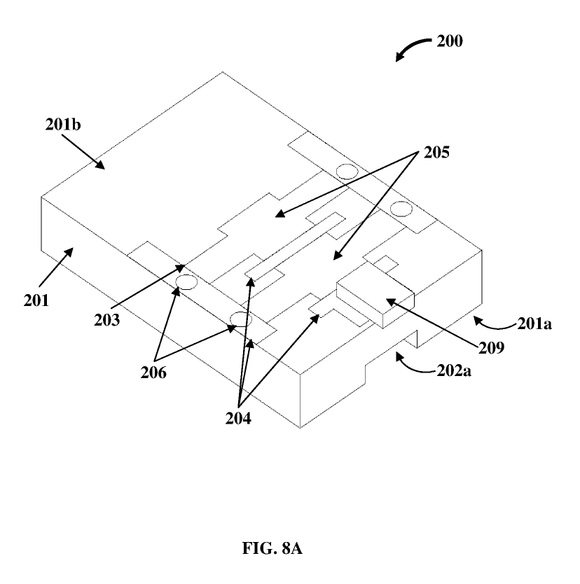

FIG. 7 exemplarily illustrates a graphical representation of return loss performance of the termination chip 200 with an operating frequency of 30 GHz exemplarily illustrated in FIGS. 6A-6C. A simulation is performed by using a high frequency structural simulator (HFSS) to evaluate the design of the termination chip 200. FIG. 7 exemplarily illustrates the performance of the termination chip 200 resulting from the reduction in the capacitance and material loss caused by the introduction of the air gap 202a on the substrate 201 and by the design of the termination chip 200. The termination chip 200 with an air gap 202a at a selected location on the substrate 201 exemplarily illustrated in FIG. 6A and FIG. 6C, is simulated at an operating frequency of 30 GHz using the HFSS. The benefit of reducing the capacitance of the termination chip 200 with an operating frequency of 30 GHz is exemplarily illustrated in FIG. 7. The return loss obtained for the termination chip 200 operating at 30 GHz is, for example, more than about 35 dB.

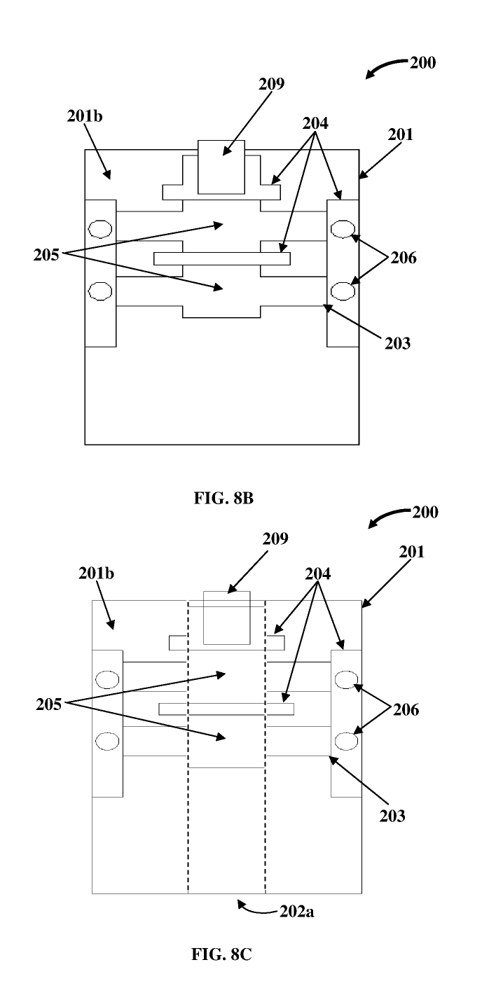

FIGS. 8A-8C exemplarily illustrate different views of a termination chip 200 with an operating frequency of 40 GHz, showing components of the electronic circuitry 203 of the termination chip 200. FIG. 8A exemplarily illustrates a front, top perspective view of the termination chip 200 with an operating frequency of 40 GHz. FIG. 8B exemplarily illustrates a top plan view of the termination chip 200 with an operating frequency of 40 GHz. FIG. 8C exemplarily illustrates a top plan view of the termination chip 200 with an operating frequency of 40 GHz, showing an air gap 202a in hidden lines in the termination chip 200. Example dimensions of the air gap 202a of the termination chip 200 exemplarily illustrated in FIG. 8C are width=20.0 mils; length=5.0 mils; and depth=100.0 mils. These dimensions can be adjusted depending on the power, frequency, and electrical specifications of the termination chip 200. The layer of epoxy 207 exemplarily illustrated in FIG. 2B, is not shown in FIGS. 8A-8C.

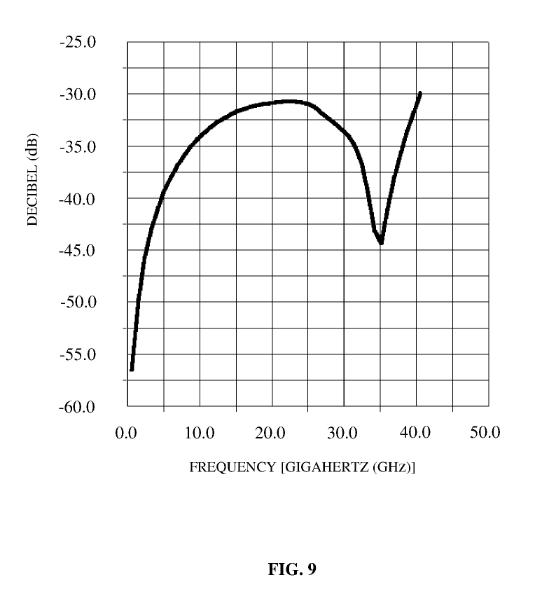

FIG. 9 exemplarily illustrates a graphical representation of return loss performance of the termination chip 200 with an operating frequency of 40 GHz exemplarily illustrated in FIGS. 8A-8C. A simulation is performed by using a high frequency structural simulator (HFSS) to evaluate the design of the termination chip 200. FIG. 9 exemplarily illustrates another example of the performance of the termination chip 200 caused by the air gap 202a and the design of the termination chip 200. The termination chip 200 with an air gap 202a at a selected location on the substrate 201 exemplarily illustrated in FIG. 8A and FIG. 8C, is simulated at an operating frequency of 40 GHz using the HFSS. The benefit of reducing the capacitance of the termination chip 200 with an operating frequency of 40 GHz is exemplarily illustrated in FIG. 9. The return loss obtained for the termination chip 200 operating at 40 GHz is, for example, more than about 30 dB.

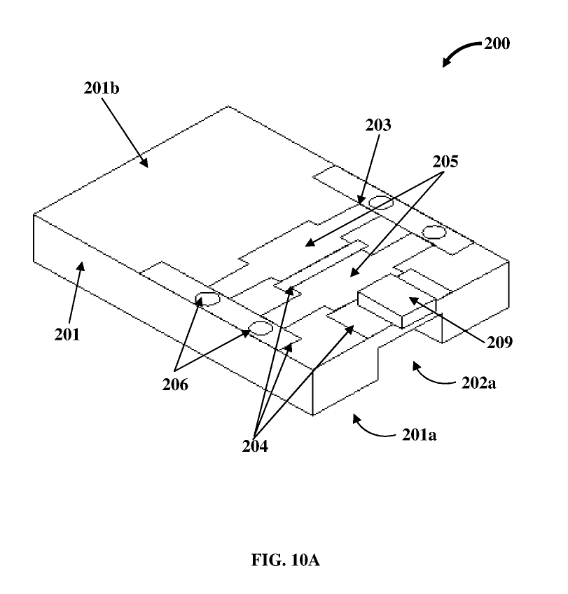

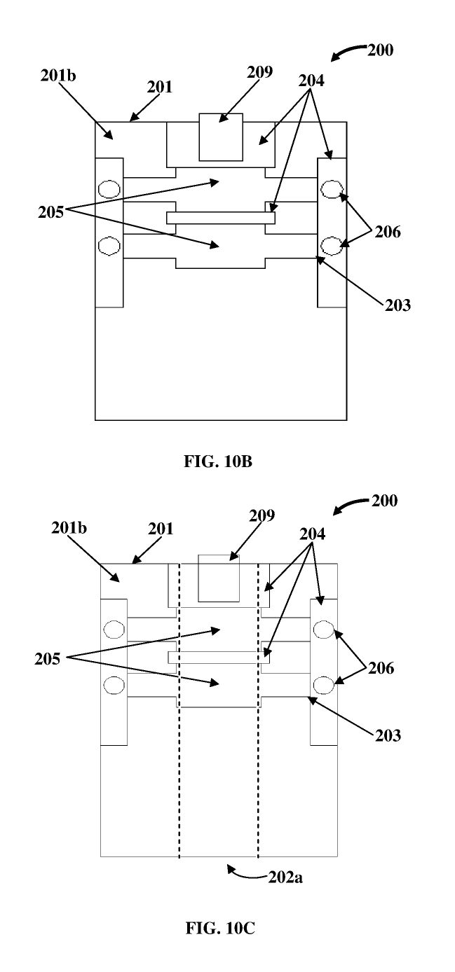

FIGS. 10A-10C exemplarily illustrate different views of a termination chip 200 with an operating frequency of 50 GHz, showing components of the electronic circuitry 203 of the termination chip 200. FIG. 10A exemplarily illustrates a front, top perspective view of the termination chip 200 with an operating frequency of 50 GHz. FIG. 10B exemplarily illustrates a top plan view of the termination chip 200 with an operating frequency of 50 GHz. FIG. 10C exemplarily illustrates a top plan view of the termination chip 200 with an operating frequency of 50 GHz, showing an air gap 202a in hidden lines in the termination chip 200. Example dimensions of the air gap 202a of the termination chip 200 exemplarily illustrated in FIG. 10C are width=23.0 mils; length=10.0 mils; and depth=100.0 mils. These dimensions can be adjusted depending on the power, frequency, and electrical specifications of the termination chip 200. The layer of epoxy 207 exemplarily illustrated in FIG. 2B, is not shown in FIGS. 10A-10C. The electronic circuitry 203 of the termination chip 200 is modified to obtain different operating frequencies for the termination chip 200, for example, 30 GHz as exemplarily illustrated in FIGS. 6A-6C, 40 GHz as exemplarily illustrated in FIGS. 8A-8C, and 50 GHz as exemplarily illustrated in FIGS. 10A-10C. Adjusting the width and the length of the resistive regions 205 to obtain improved electrical performance based on the design frequency and then adjusting the value of the resistivity to obtain a 50 ohms termination is addressed in the method disclosed herein. For example, when configuring a termination chip 200 at a frequency of about 50 GHz, the surface areas of the resistive region 205 are configured to be less than those of a 40 GHz termination, since the wavelength of the frequency at 50 GHz is less than at 40 GHz, at 30 GHz, and so on.

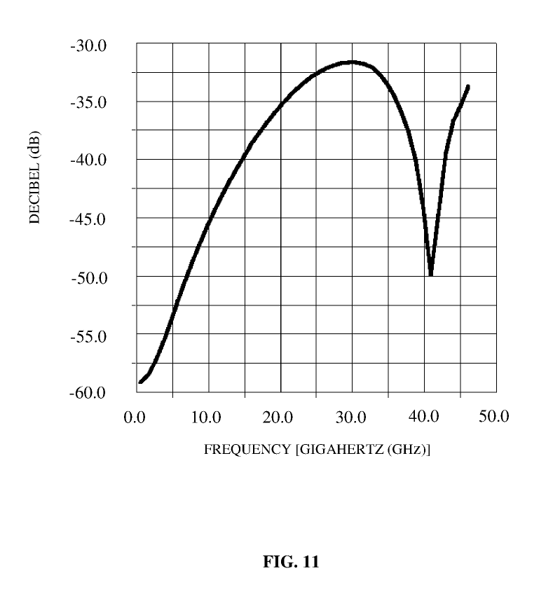

FIG. 11 exemplarily illustrates a graphical representation of return loss performance of the termination chip 200 with an operating frequency of 50 GHz exemplarily illustrated in FIGS. 10A-10C. A simulation is performed by using a high frequency structural simulator (HFSS) to evaluate the design of the termination chip 200. The termination chip 200 with an air gap 202a at a selected location on the substrate 201 exemplarily illustrated in FIG. 10A and FIG. 10C is simulated at an operating frequency of 50 GHz using the HFSS. The benefit of reducing the capacitance of the termination chip 200 with an operating frequency of 50 GHz is exemplarily illustrated in FIG. 11. The return loss obtained for the termination chip 200 operating at 50 GHz is, for example, more than about 30 dB.

FIGS. 12A-12B exemplarily illustrate different perspective views of an attenuator chip 1200. FIG. 12A exemplarily illustrates a front, top perspective view of the attenuator chip 1200. FIG. 12B exemplarily illustrates a rear, top perspective view of the attenuator chip 1200. The attenuator chip 1200 comprises a substrate 1201 and two connector tabs 1205 and 1206. The connector tabs comprise, for example, an input connector tab 1205 and an output connector tab 1206. The input connector tab 1205 is positioned approximately at a front mid position 1201f of an upper section 1201b of the substrate 1201 and at a front end 1201c of the substrate 1201. The output connector tab 1206 is positioned approximately at a rear mid position 1201g of the upper section 1201b of the substrate 1201 and at a rear end 1201d of the substrate 1201.

In an embodiment, the attenuator chip 1200 can be a standalone attenuator chip or can be inserted into a coaxial housing (not shown), similar to a termination chip 200 disclosed in the detailed description of FIGS. 2A-2E. As exemplarily illustrated in FIGS. 12A-12B, an input port 1204a and one output port 1204b are configured on the upper section 1201b of the substrate 1201. The input port 1204a and the output port 1204b are configured to house the connector tabs 1205 and 1206 respectively, or to attach to a pin (not shown) of each of one or more coaxial connectors (not shown). The input port 1204a for the input connector tab 1205 is positioned approximately at the mid position 1201f of the front end 1201c of the upper section 1201b of the substrate 1201. The output port 1204b for the output connector tab 1206 is positioned approximately at the mid position 1201g of the rear end 1201d of the upper section 1201b of the substrate 1201. After the design of the electronic circuitry 1207 of the attenuator chip 1200 is fabricated on the upper section 1201b of the substrate 1201, a layer of epoxy 1203 is screen printed on the upper section 1201b of the substrate 1201 excluding the locations of the input port 1204a and the output port 1204b of the attenuator chip 1200, similar to the termination chip 200 disclosed in the detailed description of FIGS. 2A-2C. The upper section 1201b of the substrate 1201 is covered with the layer of epoxy 1203 after the attenuator chip 1200 is configured. The layer of epoxy 1203 is configured to protect the attenuator chip 1200 from an external environment. The input connector tab 1205 and the output connector tab 1206 are then attached to the input port 1204a and the output port 1204b of the attenuator chip 1200 respectively. In an embodiment, if the attenuator chip 1200 is to be inserted into a coaxial housing, then the input port 1204a and the output port 1204b are left unattached, so that the input port 1204a and the output port 1204b can be attached to a pin of each of one or more coaxial connectors, similar to the termination chip 200 disclosed in the detailed description of FIGS. 2A-2C.

In the method disclosed herein, an air gap 1202a is created in a lower section 1201a of the substrate 1201 using a dicing mechanism. For example, a generally rectangular slot 1202 is made in the lower section 1201a of the substrate 1201 by removing a portion of the substrate 1201 from the lower section 1201a of the substrate 1201. The slot 1202 is positioned approximately at a mid-section 1201e of the substrate 1201. The slot 1202 that defines the air gap 1202a extends from a front end 1201c to a rear end 1201d opposing the front end 1201c of the substrate 1201. The power dissipation of the attenuator chip 1200 varies from about 5 watts (W) to about 15 W, which can be increased based on the dimension of the electronic circuitry 1207, the dimension and the location of the air gap 1202a, the material of the attenuator chip 1200, and the technology used to build the attenuator chip 1200. The width and the locations of the air gap 1202a can be altered to increase the power dissipation of the attenuator chip 1200.

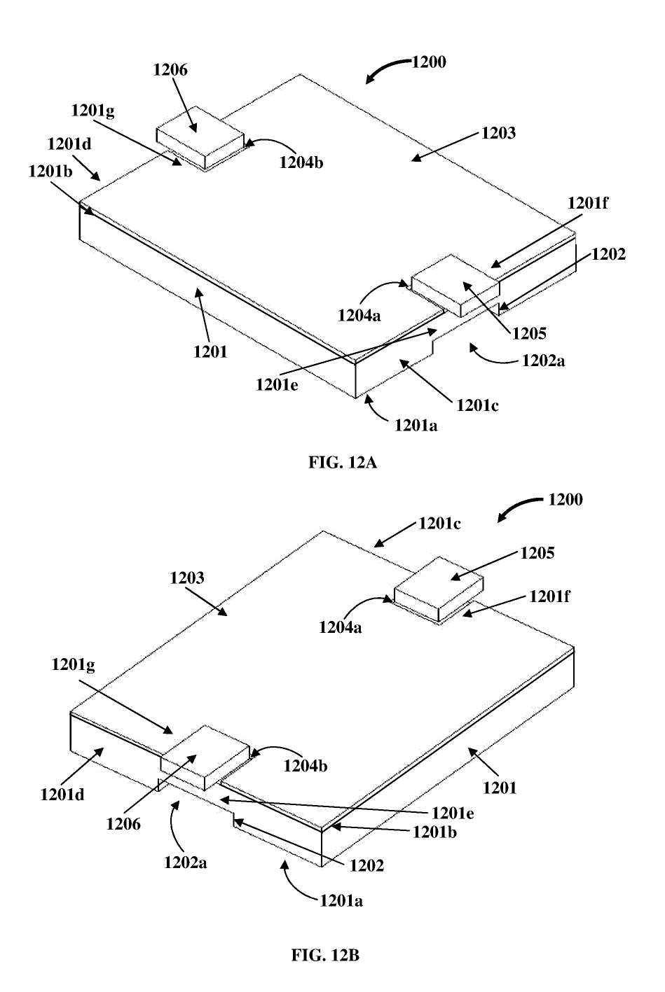

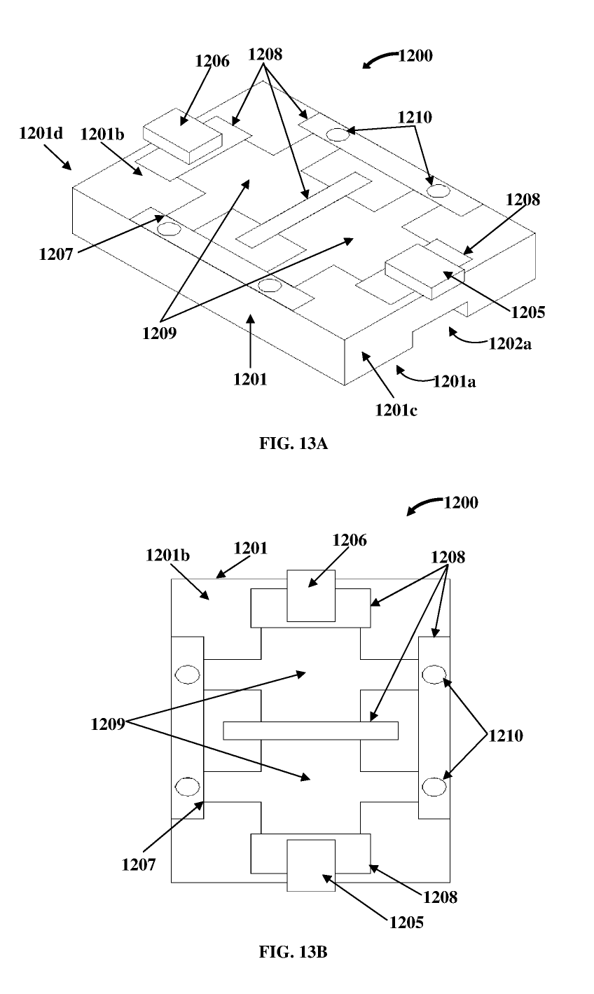

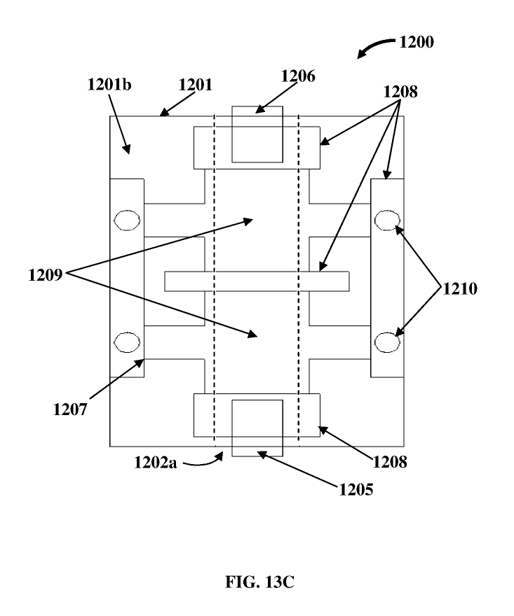

FIGS. 13A-13C exemplarily illustrate different views of the attenuator chip 1200, showing components of the electronic circuitry 1207 of the attenuator chip 1200. The electronic circuitry 1207 of the attenuator chip 1200 comprises one or more electrodes 1208 made of high conductivity metals, one or more resistive regions 1209, and one or more vias 1210. FIG. 13A exemplarily illustrates a front, top perspective view of the attenuator chip 1200. FIG. 13B exemplarily illustrates a top plan view of the attenuator chip 1200. FIG. 13C exemplarily illustrates a top plan view of the attenuator chip 1200, showing an air gap 1202a in hidden lines in the attenuator chip 1200. Example dimensions of the air gap 1202a of the attenuator chip 1200 exemplarily illustrated in FIG. 13C are width=20.0 mils; length=5.0 mils; and depth=100.0 mils. These dimensions can be adjusted depending on the power, frequency, and electrical specifications of the attenuator chip 1200. Similar to terminations, attenuators can also be configured in a leaded chip form, for example, as a surface-mount or in a coaxial housing (not shown). If the attenuator chip 1200 disclosed herein is inserted in the coaxial housing, the attenuator chip 1200 will dissipate more power than a conventional coaxial attenuator, as will the termination chip 200 disclosed in the detailed description of FIGS. 2A-2E, because a solid ground connection is present, through the vias 1210, from the upper section 1201b of the substrate 1201 to a metalized lower section 1201a or bottom section, for example, the legs on each side of the air gap 1202a of the substrate 1201. Hence, the ground plane surface area for the attenuator chip 1200 enclosed in the coaxial housing is large, thereby increasing power dissipation. In the method disclosed herein, the electronic circuitry 1207 for an attenuator chip 1200 of different attenuation values, for example, 20 dB, 30 dB, etc., is determined by cascading two identical electronic circuitries of T-type network attenuators in series. In an example, a 20 dB attenuator chip 1200 is configured by cascading a first resistive section of a 10 dB attenuator circuit and a second resistive section of a 10 dB attenuator circuit to create an equivalent 20 dB attenuator circuit.

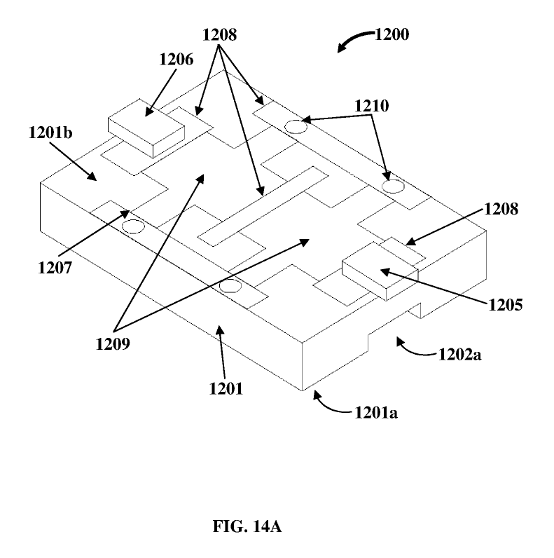

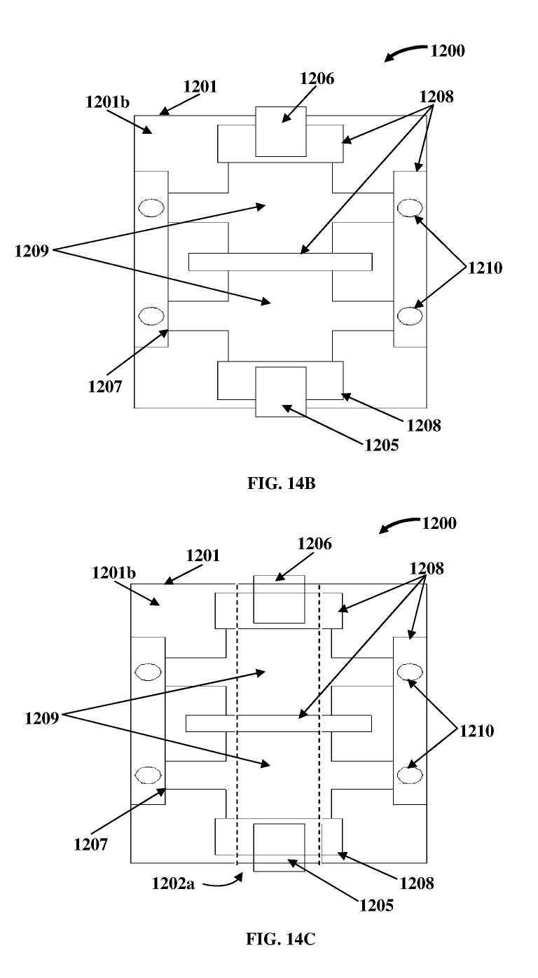

FIGS. 14A-14C exemplarily illustrate different views of a 20 dB attenuator chip 1200 with an operating frequency of 20 GHz. FIG. 14A exemplarily illustrates a front, top perspective view of the 20 dB attenuator chip 1200 with an operating frequency of 20 GHz. FIG. 14B exemplarily illustrates a top plan view of the 20 dB attenuator chip 1200. FIG. 14C exemplarily illustrates a top plan view of the 20 dB attenuator chip 1200 with an operating frequency of 20 GHz, showing an air gap 1202a in hidden lines in the 20 dB attenuator chip 1200. Example dimensions of the air gap 1202a of the 20 dB attenuator chip 1200 exemplarily illustrated in FIG. 14C are width=20.0 mils; length=5.0 mils; and depth=100.0 mils. These dimensions can be adjusted depending on the power, frequency, and electrical specifications of the attenuator chip 1200. The layer of epoxy 1203 exemplarily illustrated in FIGS. 12A-12B, is not shown in FIGS. 14A-14C.

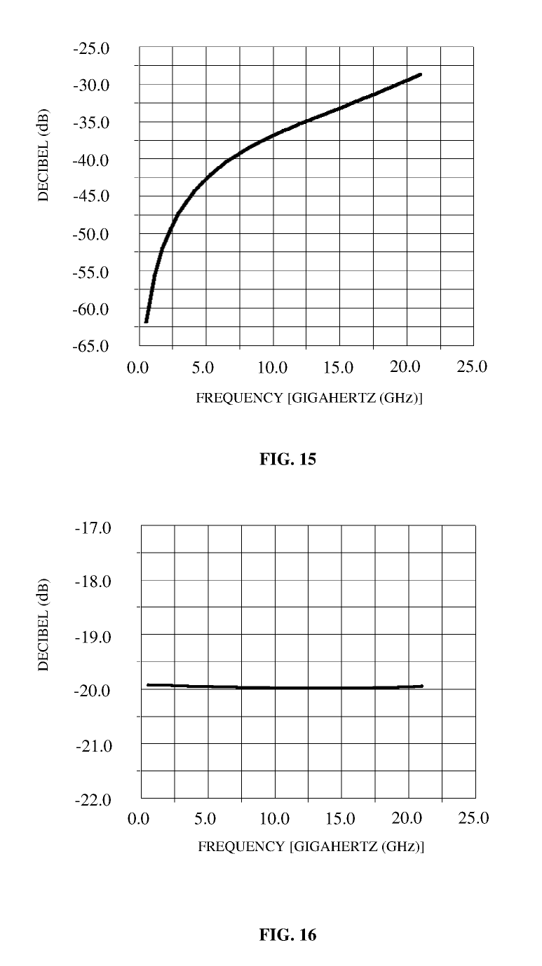

FIG. 15 exemplarily illustrates a graphical representation of return loss performance of the 20 dB attenuator chip 1200 with an operating frequency of 20 GHz exemplarily illustrated in FIGS. 14A-14C. A simulation is performed by using a high frequency structural simulator (HFSS) to evaluate the design of the attenuator chip 1200. As exemplarily illustrated in FIG. 15, there is an improvement in the return losses of the attenuator chip 1200, which is caused by the design of the attenuator chip 1200 and by the introduction of the air gap 1202a in the substrate 1201 exemplarily illustrated in FIG. 14A and FIG. 14C, which reduces the capacitance and the insertion loss of the substrate material. The benefit of reducing the capacitance of the 20 dB attenuator chip 1200 on the return losses of the 20 dB attenuator chip 1200 is exemplarily illustrated in FIG. 15. The return loss of the 20 dB attenuator chip 1200 with the operating frequency of 20 GHz is, for example, more than about 30 dB.

FIG. 16 exemplarily illustrates a graphical representation of attenuation performance of the 20 dB attenuator chip 1200 with an operating frequency of 20 GHz exemplarily illustrated in FIGS. 14A-14C. A simulation is performed by using a high frequency structural simulator (HFSS) to evaluate the design of the attenuator chip 1200. As exemplarily illustrated in FIG. 16, there is an improvement in the flatness of the attenuation of the attenuator chip 1200, which is caused by the introduction of the air gap 1202a in the substrate 1201 exemplarily illustrated in FIG. 14A and FIG. 14C and by the design of the attenuator chip 1200, which reduces the capacitance and the insertion loss of the substrate material. The benefit of reducing the insertion loss and the capacitance on the attenuation performance of the 20 dB attenuator chip 1200 with the operating frequency of 20 GHz is exemplarily illustrated in FIG. 16. The flatness of the attenuation of the attenuator chip 1200 is, for example, within a range of about +/−0.1 dB.

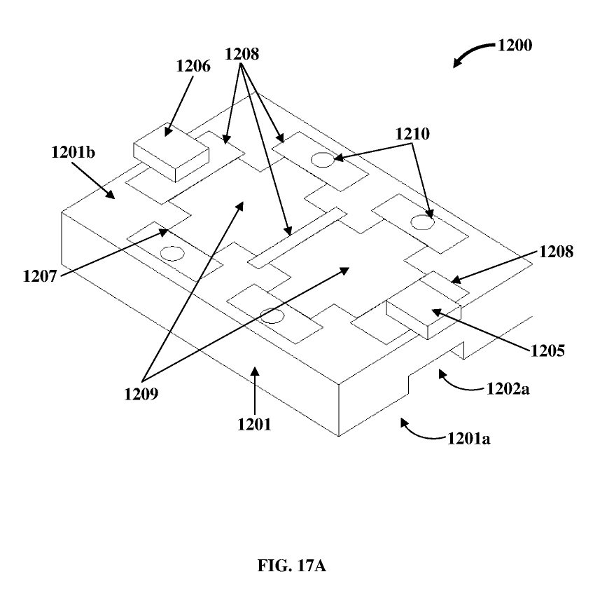

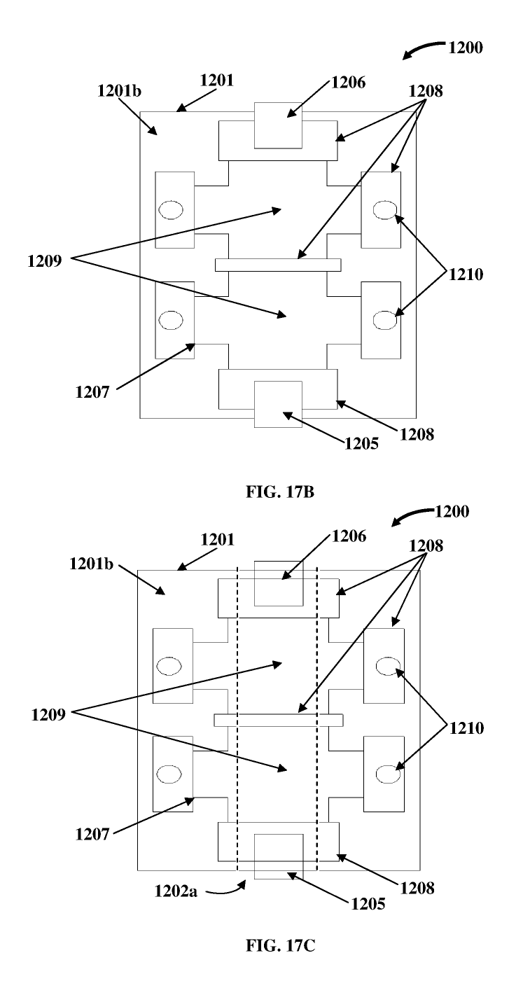

FIGS. 17A-17C exemplarily illustrate different views of a 30 dB attenuator chip 1200 with an operating frequency of 20 GHz. FIG. 17A exemplarily illustrates a front, top perspective view of the 30 dB attenuator chip 1200 with an operating frequency of 20 GHz. FIG. 17B exemplarily illustrates a top plan view of the 30 dB attenuator chip 1200 with an operating frequency of 20 GHz. FIG. 17C exemplarily illustrates a top plan view of the 30 dB attenuator chip 1200 with an operating frequency of 20 GHz, showing an air gap 1202a in hidden lines in the 30 dB attenuator chip 1200. Example dimensions of the air gap 1202a of the 30 dB attenuator chip 1200 exemplarily illustrated in FIG. 17C are width=20.0 mils; length=5.0 mils; and depth=100.0 mils. These dimensions can be adjusted depending on the power, frequency, and electrical specifications of the attenuator chip 1200. The layer of epoxy 1203 exemplarily illustrated in FIGS. 12A-12B, is not shown in FIGS. 17A-17C.

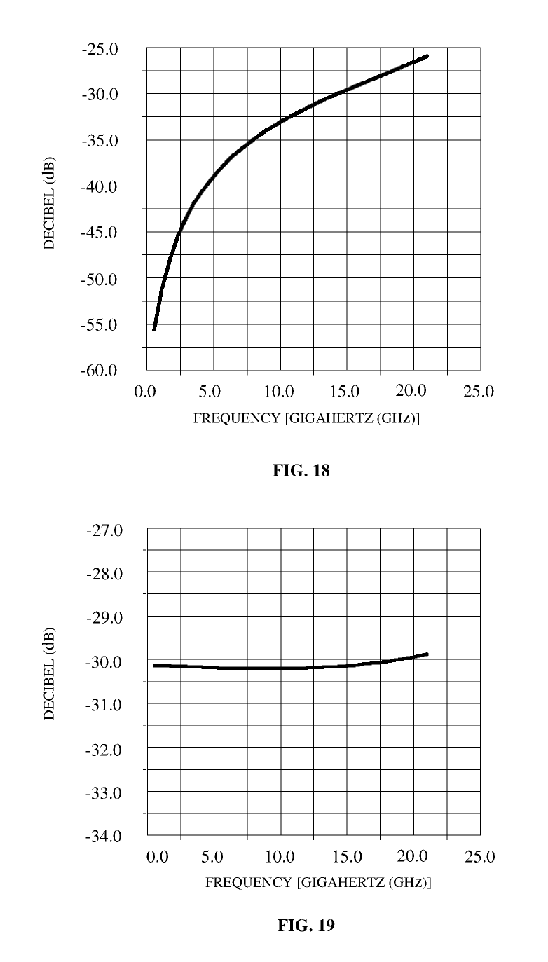

FIG. 18 exemplarily illustrates a graphical representation of return loss performance of the 30 dB attenuator chip 1200 with an operating frequency of 20 GHz exemplarily illustrated in FIGS. 17A-17C. As exemplarily illustrated in FIG. 18, there is an improvement in the return loss of the attenuator chip 1200, which is caused by the design of the attenuator chip 1200 and by the introduction of the air gap 1202a in the substrate 1201 exemplarily illustrated in FIG. 14A and FIG. 14C, which reduces the capacitance and the insertion loss of the substrate material. The benefit of reducing the capacitance of the 30 dB attenuator chip 1200 on the return losses of the 30 dB attenuator chip 1200 is exemplarily illustrated in FIG. 18. The return loss of the 30 dB attenuator chip 1200 with the operating frequency of 20 GHz is, for example, more than about 26 dB.

FIG. 19 exemplarily illustrates a graphical representation of attenuation performance of the 30 decibel (dB) attenuator chip 1200 with an operating frequency of 20 GHz exemplarily illustrated in FIGS. 17A-17C. A simulation is performed by using a high frequency structural simulator (HFSS) to evaluate the design of the attenuator chip 1200. As exemplarily illustrated in FIG. 19, there is an improvement in the flatness of attenuation of the attenuator chip 1200, which is caused by the design of the attenuator chip 1200 and by the introduction of the air gap 1202a in the substrate 1201 exemplarily illustrated in FIG. 17A and FIG. 17C, which reduces the capacitance and the insertion loss of the substrate material. The benefit of reducing the insertion loss and the capacitance on the attenuation performance of the 30 dB attenuator chip 1200 with the operating frequency of 20 GHz is exemplarily illustrated in FIG. 19. The flatness of the attenuation of the 30 dB attenuator chip 1200 is, for example, within a range of about +/−0.1 dB.

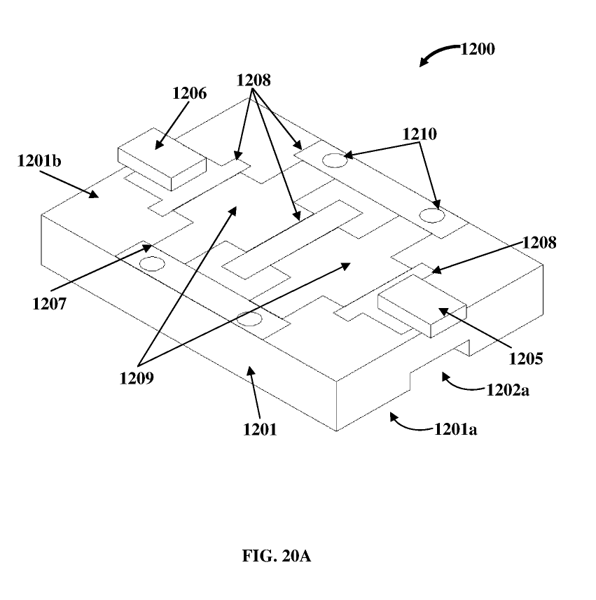

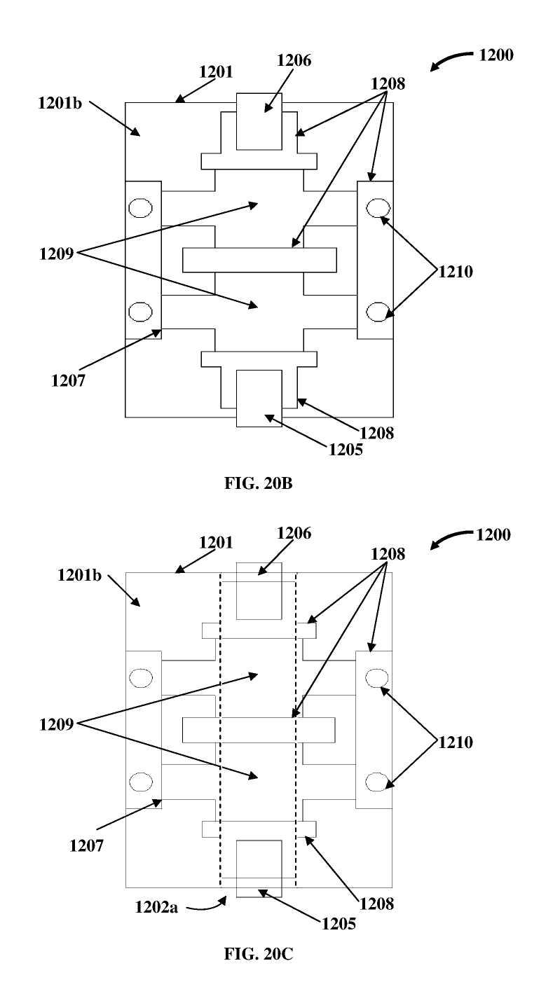

FIGS. 20A-20C exemplarily illustrate different views of a 20 dB attenuator chip 1200 with an operating frequency of 30 GHz. FIG. FIG. 20A exemplarily illustrates a front, top perspective view of the 20 dB attenuator chip 1200 with an operating frequency of 30 GHz. FIG. 20B exemplarily illustrates a top plan view of the 20 dB attenuator chip 1200 with an operating frequency of 30 GHz. FIG. 20C exemplarily illustrates a top plan view of the 20 dB attenuator chip 1200 with an operating frequency of 30 GHz, showing an air gap 1202a in the 20 dB attenuator chip 1200. Example dimensions of the air gap 1202a of the 20 dB attenuator chip 1200 exemplarily illustrated in FIG. 20C are width=20.0 mils; length=5.0 mils; and depth=100.0 mils. These dimensions can be adjusted depending on the power, frequency, and electrical specifications of the attenuator chip 1200. The layer of epoxy 1203 exemplarily illustrated in FIGS. 12A-12B, is not shown in FIGS. 20A-20C.

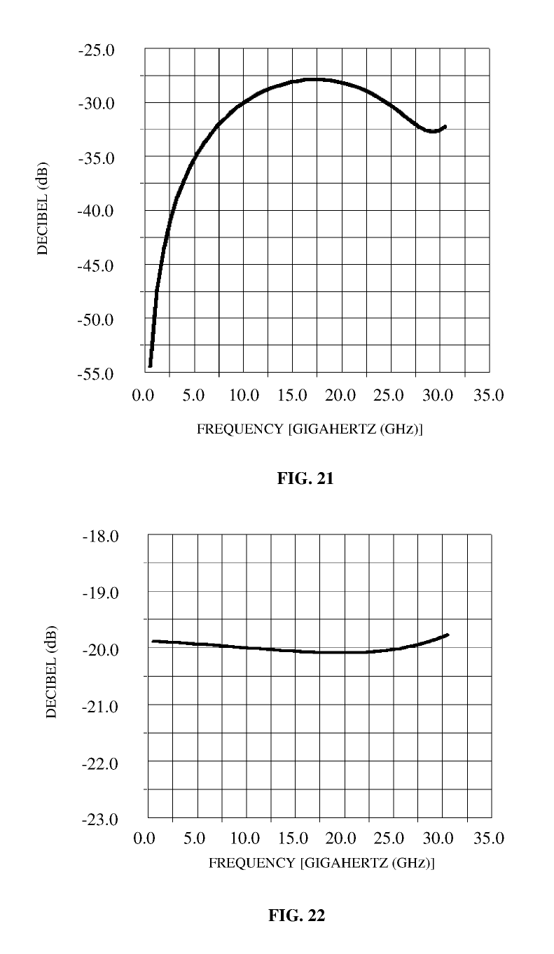

FIG. 21 exemplarily illustrates a graphical representation of return loss performance of the 20 dB attenuator chip 1200 with an operating frequency of 30 GHz exemplarily illustrated in FIGS. 20A-20C. A simulation is performed by using a high frequency structural simulator (HFSS) to evaluate the design of the attenuator chip 1200. As exemplarily illustrated in FIG. 21, there is an improvement in the return loss of the attenuator chip 1200, which is caused by the design of the attenuator chip 1200 and by the introduction of the air gap 1202a in the substrate 1201 exemplarily illustrated in FIG. 20A and FIG. 20C, which reduces the capacitance and the insertion loss of the substrate material. The benefit of reducing the capacitance of the 20 dB attenuator chip 1200 on the return loss performance of the 20 dB attenuator chip 1200 is exemplarily illustrated in FIG. 21. The return loss of the 20 dB attenuator chip 1200 with the operating frequency of 30 GHz is, for example, more than about 27 dB.

FIG. 22 exemplarily illustrates a graphical representation of attenuation performance of the 20 dB attenuator chip 1200 with an operating frequency of 30 GHz exemplarily illustrated in FIGS. 20A-20C. A simulation is performed by using a high frequency structural simulator (HFSS) to evaluate the design of the attenuator chip 1200. As exemplarily illustrated in FIG. 22, there is an improvement in the flatness of attenuation of the attenuator chip 1200, which is caused by the design of the attenuator chip 1200 and by the introduction of the air gap 1202a in the substrate 1201 exemplarily illustrated in FIG. 20A and FIG. 20C, which reduces the capacitance and the insertion loss of the substrate material. The benefit of reducing the insertion loss and the capacitance on the attenuation performance of the 20 dB attenuator chip 1200 with the operating frequency of 30 GHz is exemplarily illustrated in FIG. 22. The flatness of the attenuation of the 20 dB attenuator chip 1200 is, for example, within a range of about +/−0.1 dB.

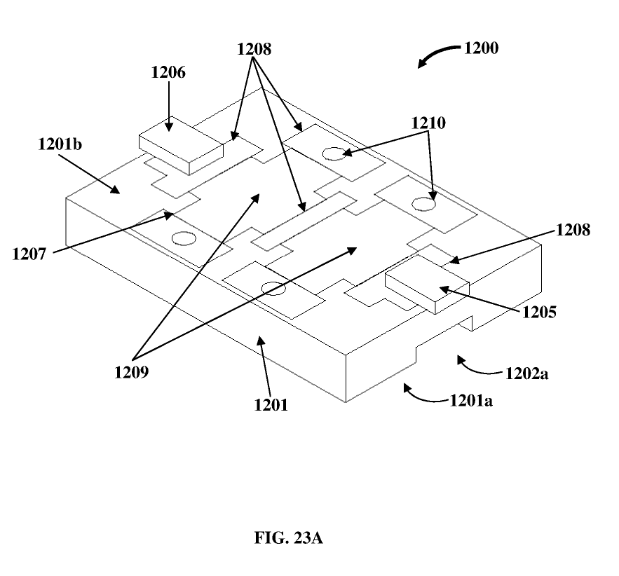

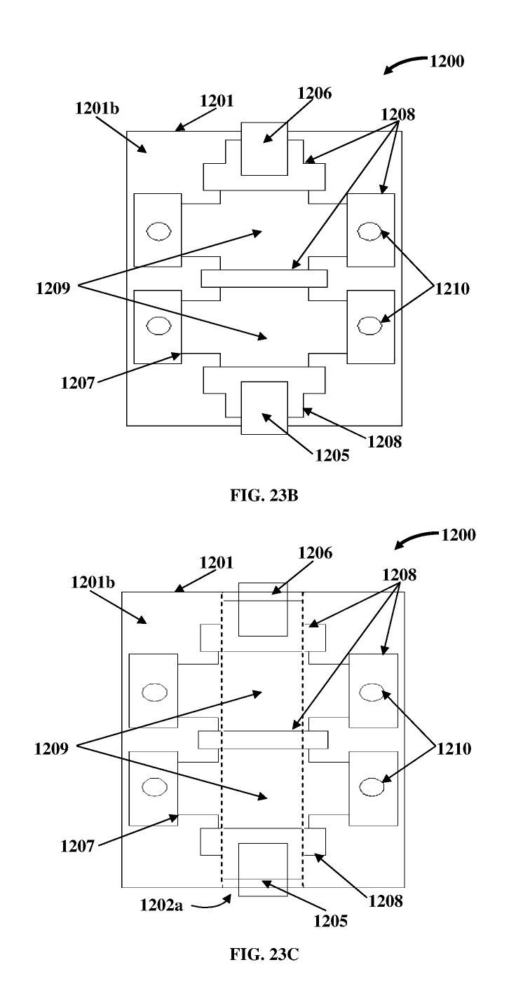

FIGS. 23A-23C exemplarily illustrate different views of a 30 dB attenuator chip 1200 with an operating frequency of 30 GHz. FIG. 23A exemplarily illustrates a front, top perspective view of the 30 dB attenuator chip 1200 with an operating frequency of 30 GHz. FIG. 23B exemplarily illustrates a top plan view of the 30 dB attenuator chip 1200 with an operating frequency of 30 GHz. FIG. 23C exemplarily illustrates a top plan view of the 30 dB attenuator chip 1200 with an operating frequency of 30 GHz, showing an air gap 1202a in hidden lines in the 30 dB attenuator chip 1200. Example dimensions of the air gap 1202a of the 30 dB attenuator chip 1200 exemplarily illustrated in FIG. 23C are width=20.0 mils; length=5.0 mils; and depth=100.0 mils. These dimensions can be adjusted depending on the power, frequency, and electrical specifications of the attenuator chip 1200. The layer of epoxy 1203 exemplarily illustrated in FIGS. 12A-12B, is not shown in FIGS. 23A-23C.

FIG. 24 exemplarily illustrates a graphical representation of return loss performance of the 30 dB attenuator chip 1200 with an operating frequency of 30 GHz exemplarily illustrated in FIGS. 23A-23C. A simulation is performed by using a high frequency structural simulator (HFSS) to evaluate the design of the 30 dB attenuator chip 1200. As exemplarily illustrated in FIG. 24, there is an improvement in the return loss of the 30 dB attenuator chip 1200, which is caused by the design of the 30 dB attenuator chip 1200 and by the introduction of the air gap 1202a in the substrate 1201 exemplarily illustrated in FIG. 23A and FIG. 23C, which reduces the capacitance and the insertion loss of the substrate material. The benefit of reducing the capacitance of the 30 dB attenuator chip 1200 on the return loss performance of the 30 dB attenuator chip 1200 is exemplarily illustrated in FIG. 24. The return loss of the 30 dB attenuator chip 1200 with the operating frequency of 30 GHz is, for example, more than about 27 dB.

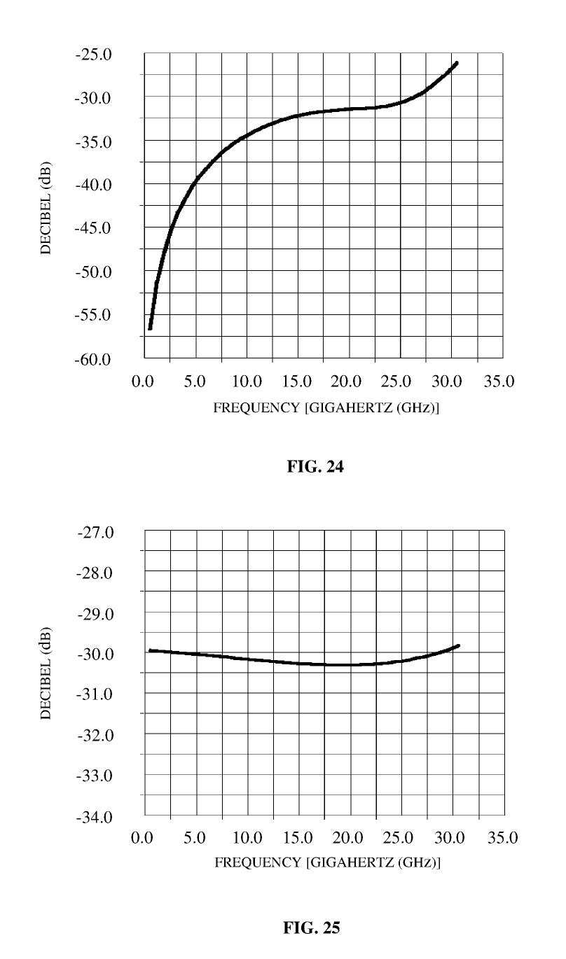

FIG. 25 exemplarily illustrates a graphical representation of attenuation performance of the 30 dB attenuator chip 1200 with an operating frequency of 30 GHz exemplarily illustrated in FIGS. 23A-23C. A simulation is performed by using a high frequency structural simulator (HFSS) to evaluate the design of the 30 dB attenuator chip 1200. As exemplarily illustrated in FIG. 25, there is an improvement in the flatness of attenuation of the 30 dB attenuator chip 1200, which is caused by the design of the 30 dB attenuator chip 1200 and by the introduction of the air gap 1202a in the substrate 1201 exemplarily illustrated in FIG. 23A and FIG. 23C, which reduces the capacitance and the insertion loss of the substrate material. The benefit of reducing the insertion loss and the capacitance on the attenuation performance of the 30 dB attenuator chip 1200 with the operating frequency of 30 GHz is exemplarily illustrated in FIG. 25. The flatness of the attenuation of the 30 dB attenuator chip 1200 is, for example, within a range of about +/−0.3 dB.

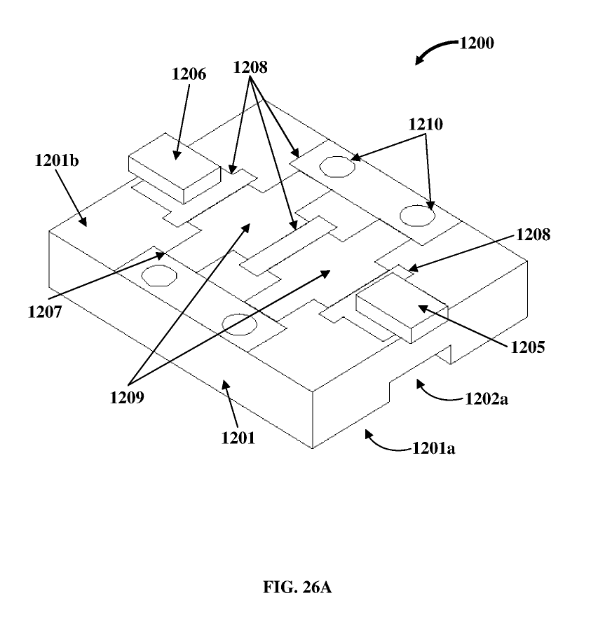

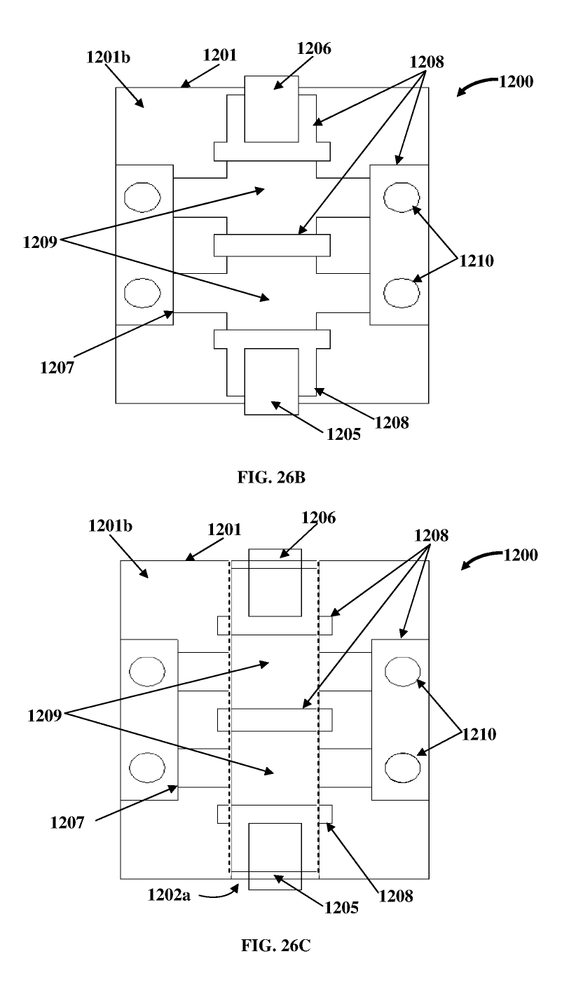

FIGS. 26A-26C exemplarily illustrate different views of a 20 dB attenuator chip 1200 with an operating frequency of 40 GHz. FIG. 26A exemplarily illustrates a front, top perspective view of the 20 dB attenuator chip 1200 with an operating frequency of 40 GHz. FIG. 26B exemplarily illustrates a top plan view of the 20 dB attenuator chip 1200 with an operating frequency of 40 GHz. FIG. 26C exemplarily illustrates a top plan view of the 20 dB attenuator chip 1200 with an operating frequency of 40 GHz, showing an air gap 1202a in hidden lines in the 20 dB attenuator chip 1200. Example dimensions of the air gap 1202a of the 20 dB attenuator chip 1200 exemplarily illustrated in FIG. 26C are width=20.0 mils; length=5.0 mils; and depth=90.0 mils. These dimensions can be adjusted depending on the power, frequency, and electrical specifications of the attenuator chip 1200. The layer of epoxy 1203 exemplarily illustrated in FIGS. 12A-12B, is not shown in FIGS. 26A-26C.

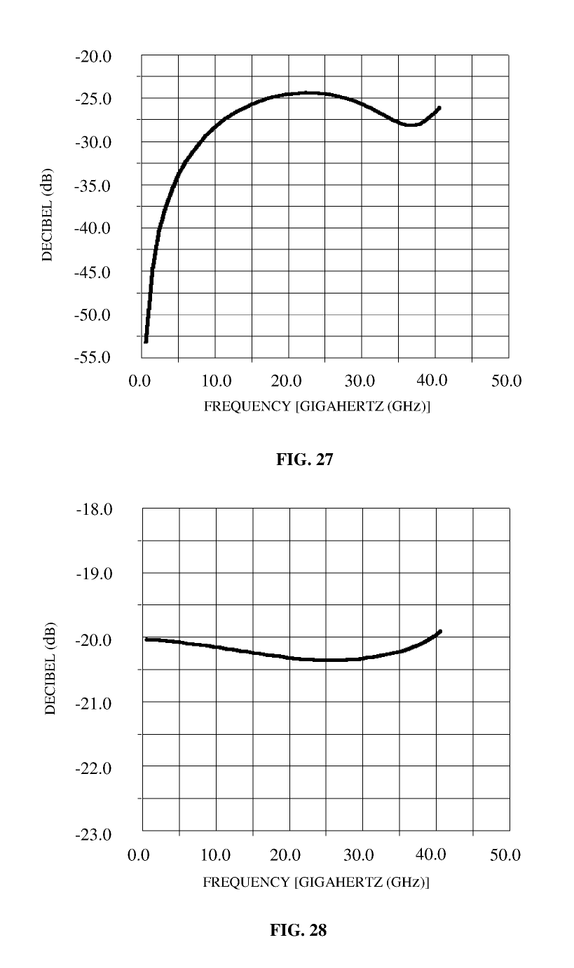

FIG. 27 exemplarily illustrates a graphical representation of return loss performance of the 20 dB attenuator chip 1200 with an operating frequency of 40 GHz exemplarily illustrated in FIGS. 26A-26C. A simulation is performed by using a high frequency structural simulator (HFSS) to evaluate the design of the attenuator chip 1200. As exemplarily illustrated in FIG. 27, there is an improvement in the return loss of the attenuator chip 1200, which is caused by the design of the attenuator chip 1200 and by the introduction of the air gap 1202a in the substrate 1201 exemplarily illustrated in FIG. 26A and FIG. 26C, which reduces the capacitance and the insertion loss of the substrate material. The benefit of reducing the capacitance of the 20 dB attenuator chip 1200 on the return loss performance of the 20 dB attenuator chip 1200 is exemplarily illustrated in FIG. 27. The return loss of the 20 dB attenuator chip 1200 with the operating frequency of 40 GHz is, for example, more than about 24 dB.

FIG. 28 exemplarily illustrates a graphical representation of attenuation performance of the 20 dB attenuator chip 1200 with an operating frequency of 40 GHz exemplarily illustrated in FIGS. 26A-26C. A simulation is performed by using a high frequency structural simulator (HFSS) to evaluate the design of the attenuator chip 1200. As exemplarily illustrated in FIG. 28, there is an improvement in the flatness of attenuation of the attenuator chip 1200, which is caused by the design of the attenuator chip 1200 and by the introduction of the air gap 1202a in the substrate 1201 exemplarily illustrated in FIG. 26A and FIG. 26C, which reduces the capacitance and the insertion loss of the substrate material. The benefit of reducing the insertion loss and the capacitance on the attenuation performance of the 20 dB attenuator chip 1200 with the operating frequency of 40 GHz is exemplarily illustrated in FIG. 28. The flatness of the attenuation of the 20 dB attenuator chip 1200 is, for example, within a range of about +/−0.3 dB.

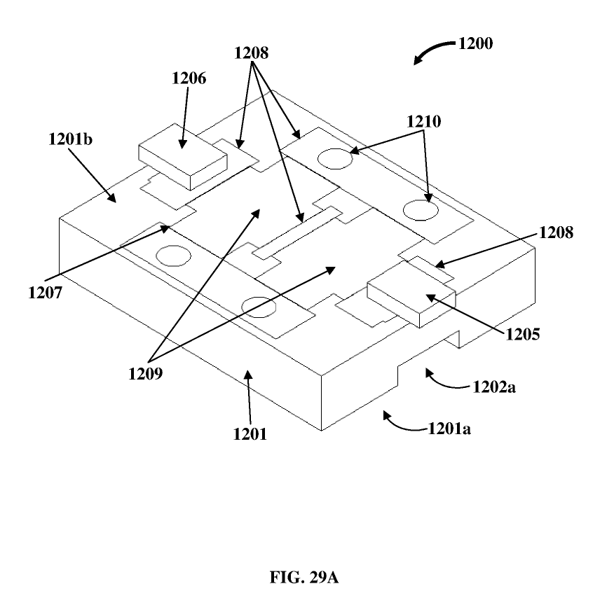

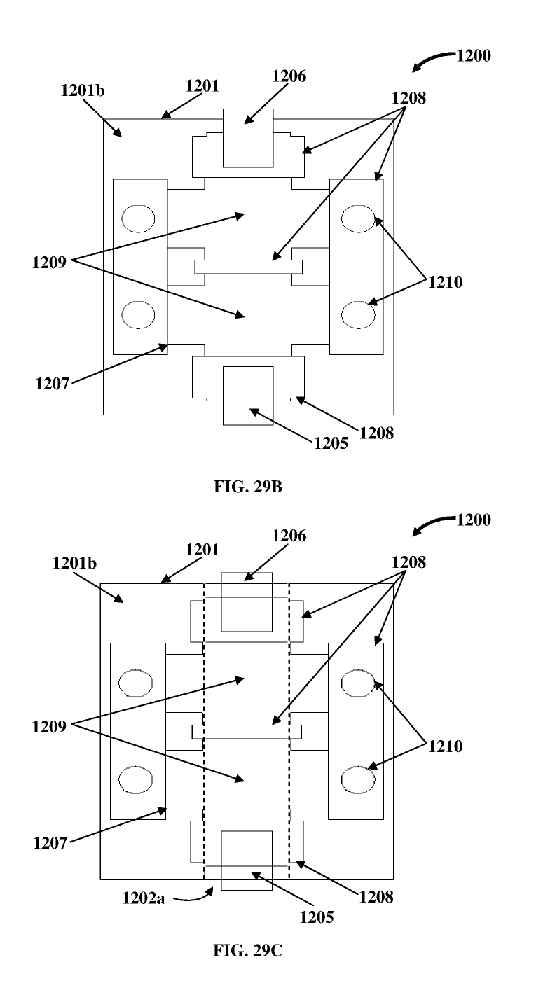

FIGS. 29A-29C exemplarily illustrate different views of a 30 dB attenuator chip 1200 with an operating frequency of 40 GHz. FIG. 29A exemplarily illustrates a front, top perspective view of the 30 dB attenuator chip 1200 with an operating frequency of 40 GHz. FIG. 29B exemplarily illustrates a top plan view of the 30 dB attenuator chip 1200 with an operating frequency of 40 GHz. FIG. 29C exemplarily illustrates a top plan view of the 30 dB attenuator chip 1200 with an operating frequency of 40 GHz, showing an air gap 1202a in hidden lines in the 30 dB attenuator chip 1200. Example dimensions of the air gap 1202a of the 30 dB attenuator chip 1200 exemplarily illustrated in FIG. 29C are width=20.0 mils; length=5.0 mils; and depth=90.0 mils. These dimensions can be adjusted depending on the power, frequency, and electrical specifications of the attenuator chip 1200. The layer of epoxy 1203 exemplarily illustrated in FIGS. 12A-12B, is not shown in FIGS. 29A-29C.

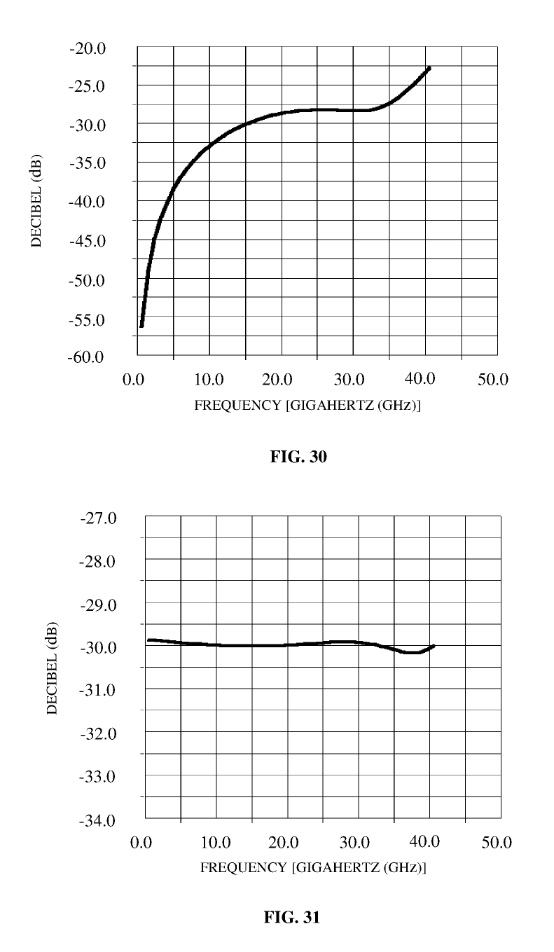

FIG. 30 exemplarily illustrates a graphical representation of return loss performance of the 30 dB attenuator chip 1200 with an operating frequency of 40 GHz exemplarily illustrated in FIGS. 29A-29C. A simulation is performed by using a high frequency structural simulator (HFSS) to evaluate the design of the attenuator chip 1200. As exemplarily illustrated in FIG. 30, there is an improvement in the return loss of the attenuator chip 1200, which is caused by the design of the attenuator chip 1200 and by the introduction of the air gap 1202a in the substrate 1201 exemplarily illustrated in FIG. 29A and FIG. 29C, which reduces the capacitance and the insertion loss of the substrate material. The benefit of reducing the capacitance of the 30 dB attenuator chip 1200 on the return loss performance of the 30 dB attenuator chip 1200 is exemplarily illustrated in FIG. 30. The return loss of the 30 dB attenuator chip 1200 with the operating frequency of 40 GHz is, for example, more than about 23 dB.

FIG. 31 exemplarily illustrates a graphical representation of attenuation performance of the 30 dB attenuator chip 1200 with an operating frequency of 40 GHz exemplarily illustrated in FIGS. 29A-29C. A simulation is performed by using a high frequency structural simulator (HFSS) to evaluate the design of the attenuator chip 1200. As exemplarily illustrated in FIG. 31, there is an improvement in the flatness of attenuation of the attenuator chip 1200, which is caused by the design of the attenuator chip 1200 and by the introduction of the air gap 1202a in the substrate 1201 exemplarily illustrated in FIG. 29A and FIG. 29C, which reduces the capacitance and the insertion loss of the substrate material. The benefit of reducing the insertion loss and the capacitance on the attenuation performance of the 30 dB attenuator chip 1200 with the operating frequency of 40 GHz is exemplarily illustrated in FIG. 31. The flatness of the attenuation of the 30 dB attenuator chip 1200 is, for example, within a range of about +/−0.1 dB.

The width and the length of the resistive regions 1209 are adjusted to obtain improved electrical performance based on the design frequency and the attenuation level. The value of resistivity is then adjusted to obtain attenuators with frequencies of 10 dB, 20 dB, 30 dB, and so on. Thus, the electronic circuitry 1207 of the attenuator chip 1200 is modified to obtain different operating frequencies for different specifications of the attenuator chip 1200, for example, an operating frequency of 20 GHz for a 30 dB attenuator chip 1200 as exemplarily illustrated in FIGS. 17A-17C, an operating frequency of 30 GHz for a 20 dB attenuator chip 1200 as exemplarily illustrated in FIGS. 20A-20C, an operating frequency of 30 GHz for a 30 dB attenuator chip 1200 as exemplarily illustrated in FIGS. 23A-23C, an operating frequency of 40 GHz for a 20 dB attenuator chip 1200 as exemplarily illustrated in FIGS. 26A-26C, and an operating frequency of 40 GHz for a 30 dB attenuator chip 1200 as exemplarily illustrated in FIGS. 29A-29C.

FIG. 32A and FIG. 32B exemplarily illustrates a front, top perspective view and a rear, top perspective view of a power divider unit 3200 respectively. The power divider unit 3200 comprises a substrate 3201, an input connector tab 3205, and two output connector tabs 3206 and 3207. The substrate 3201 of the power divider unit 3200 is, for example, a ceramic substrate. The substrate 3201 is a generally rectangular substrate comprising an upper section 3201b and a lower section 3201a. Electronic circuitry 3208, of a power divider exemplarily illustrated in FIGS. 33A-33F, is fabricated on the upper section 3201b of the substrate 3201. In the method disclosed herein, an air gap 3202a is created on the lower section 3201a of the substrate 3201 using a dicing mechanism. For example, a generally rectangular slot 3202 is made in the lower section 3201a of the substrate 3201 by removing a portion of the substrate 3201 from the lower section 3201a of the substrate 3201 using a dicing blade for creating the air gap 3202a. The slot 3202 that defines the air gap 3202a extends from one end 3201c of the substrate 3201 to the other end 3201d of the substrate 3201.

In an embodiment, the power divider unit 3200 can be a standalone unit or the substrate 3201 of the power divider unit 3200 can be inserted into a connectorized housing (not shown). An input port 3204a and two output ports 3204b and 3204c are positioned on the upper section 3201b of the substrate 3201. The input port 3204a and the output ports 3204b and 3204c are configured to house the connector tabs 3205 and 3206, 3207 respectively, or to attach to a pin of each of one or more coaxial connectors (not shown). The input port 3204a for the input connector tab 3205 is positioned approximately at the mid position 3201e of one end 3201c of the upper section 3201b of the substrate 3201. The output ports 3204b and 3204c for the output connector tabs 3206 and 3207 are positioned at the other end 3201d of the upper section 3201b of the substrate 3201. After the design of the electronic circuitry 3208 of the power divider unit 3200 is fabricated on the upper section 3201b of the substrate 3201, a layer of epoxy 3203 is screen printed on the upper section 3201b of the substrate 3201, excluding the locations of the input port 3204a and the output ports 3204b and 3204c of the power divider unit 3200, similar to the termination chip 200 disclosed in the detailed description of FIGS. 2A-2C. The upper section 3201b of the substrate 3201 is covered with the layer of epoxy 3203 to protect the unit 3200 from the external environment, after the power divider unit 3200 has been configured. The input connector tab 3205 and the output connector tabs 3206 and 3207 are then attached to the input port 3204a and the output ports 3204b and 3204c of the power divider unit 3200 respectively. In an embodiment, if the power divider unit 3200 is to be inserted into a connectorized housing, then the input port 3204a and the output ports 3204b and 3204c can be left unattached, so that the input port 3204a and the output ports 3204b and 3204c can be attached to a pin of each of one or more coaxial connectors, similar to the termination chip 200 disclosed in the detailed description of FIGS. 2A-2E, and the attenuator chip 1200 disclosed in the detailed description of FIGS. 12A-12B.

FIGS. 33A-33D exemplarily illustrate different views of the power divider unit 3200, showing the electronic circuitry 3208 of the power divider unit 3200. FIG. 33A exemplarily illustrates a top perspective view of the power divider unit 3200, showing the electronic circuitry 3208 of the power divider unit 3200. The layer of epoxy 3203 is not shown in FIGS. 33A-33D. The electronic circuitry 3208 of a power divider is fabricated on the upper section 3201b of the substrate 3201 of the power divider unit 3200. FIG. 33B exemplarily illustrates an enlarged view of a portion marked “A” of the power divider unit 3200 shown in FIG. 33A. An air gap 3202a is created on a lower section 3201a of the substrate 3201 as exemplarily illustrated in FIG. 33B.

FIG. 33C exemplarily illustrates a top plan view of the power divider unit 3200, showing the electronic circuitry 3208 of the power divider unit 3200. The electronic circuitry 3208 comprises multiple resistors 3208a and a transmission line 3208b. The resistors 3208a are configured to provide isolation between the two output connector tabs 3206 and 3207. FIGS. 33D-33E exemplarily illustrate top plan views of a power divider unit 3200, showing electronic circuitry 3208 of the power divider unit 3200 and air gaps 3202a of different widths in the power divider unit 3200 as an example of adjusting power dissipation and performance of the power divider unit 3200. FIG. 33D exemplarily illustrates a top plan view of the power divider unit 3200, showing an air gap 3202a of a larger dimension as compared to the air gap 3202a in the power divider unit 3200 exemplarily illustrated in FIG. 33E. Example dimensions of the air gap 3202a of the power divider unit 3200 exemplarily illustrated in FIG. 33D are width=700.0 mils; length=10.0 mils; and depth=2800.0 mils. Example dimensions of the air gap 3202a exemplarily illustrated in FIG. 33E are width=36.0 mils; length=10.0 mils; and depth=2370.0 mils. FIG. 33F exemplarily illustrates a top plan view of a power divider unit 3200, showing electronic circuitry 3208 of the power divider unit 3200 and different placements of multiple air gaps 3202a in the power divider unit 3200. Example dimensions of the air gap 3202a of the power divider unit 3200 exemplarily illustrated in FIG. 33F are width=20.0 mils; length=10.0 mils; and depth=700.0 mils. The above dimensions can be adjusted depending on the power, frequency, and electrical specifications of the power divider unit 3200. The width and the location of the air gaps 3202a can be altered to increase power dissipation. The layer of epoxy 3203 exemplarily illustrated in FIGS. 32A-32B, is not shown in FIGS. 33A-33F.

FIG. 34 exemplarily illustrates a graphical representation of return losses of a power divider unit 3200 exemplarily illustrated in FIGS. 32A-32B and FIGS. 33A-33D, over a frequency range. A simulation is performed by using a high frequency structural simulator (HFSS) to evaluate the design of the power divider unit 3200. The curve 3401 in FIG. 34 exemplarily illustrates the return loss of the input connector tab 3205 of the power divider unit 3200 exemplarily illustrated in FIGS. 32A-32B, FIG. 33A, and FIGS. 33C-33F. The curve 3402 exemplarily illustrates the return loss of the two output connector tabs 3206 and 3207 of the power divider unit 3200 exemplarily illustrated in FIGS. 32A-32B, FIG. 33A, and FIGS. 33C-33F. The improvement in the return losses obtained through the introduction of the air gap 3202a in the substrate 3201 exemplarily illustrated in FIGS. 33A-33D is exemplarily illustrated in FIG. 34.

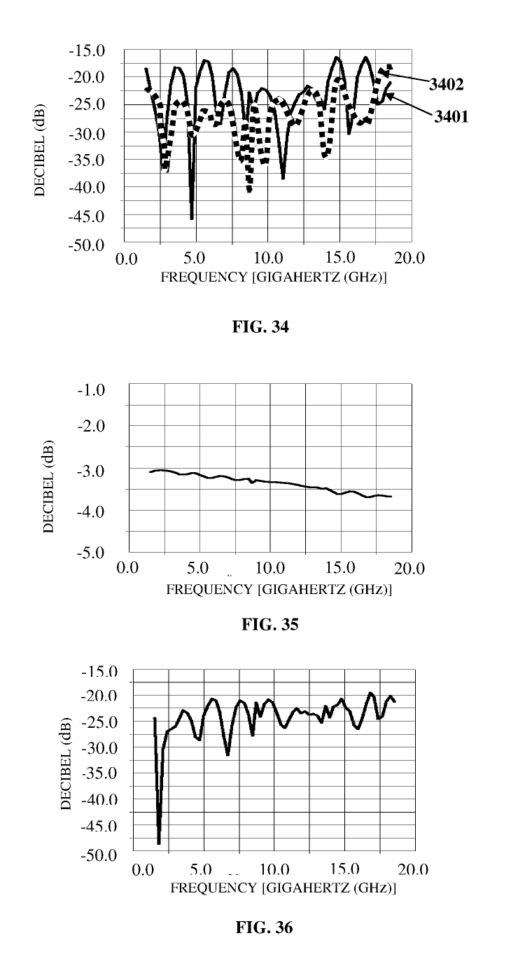

FIG. 35 exemplarily illustrates a graphical representation of insertion loss performance of a power divider unit 3200 exemplarily illustrated in FIGS. 32A-32B and FIGS. 33A-33D, over a frequency range. A simulation is performed by using a high frequency structural simulator (HFSS) to evaluate the design of the power divider unit 3200. The improvement obtained through the introduction of the air gap 3202a in the substrate 3201 exemplarily illustrated in FIGS. 33A-33D, is exemplarily illustrated in FIG. 35. The benefit of reducing the capacitance and the insertion loss of the power divider unit 3200 is exemplarily illustrated in FIG. 35. The insertion loss is, for example, about 0.7 dB.

FIG. 36 exemplarily illustrates a graphical representation of isolation performance of a power divider unit 3200 exemplarily illustrated in FIGS. 32A-32B and FIGS. 33A-33D over a frequency range. A simulation is performed by using a high frequency structural simulator (HFSS) to evaluate the design of the power divider unit 3200. The improvement obtained through the introduction of the air gap 3202a in the substrate 3201 exemplarily illustrated in FIGS. 33A-33D is exemplarily illustrated in FIG. 36. The benefit of reducing the capacitance of the power divider unit 3200 on the isolation performance of the power divider unit 3200 between the two output connector tabs 3206 and 3207 is exemplarily illustrated in FIG. 36. The isolation of the power divider unit 3200 obtained is, for example, more than about 19 dB.

FIG. 37 exemplarily illustrates a top perspective view of a 20 dB directional coupler unit 3700. The 20 dB directional coupler unit 3700 comprises a substrate 3701, and four connector tabs 3705, 3706, 3707, and 3708. The connector tabs comprise a coupled connector tab 3705, an isolated connector tab 3706, an output connector tab 3707, and an input connector tab 3708. The substrate 3701 of the 20 dB directional coupler unit 3700 is, for example, a ceramic substrate. The substrate 3701 comprises a lower section 3701a and an upper section 3701b. In the method disclosed herein, an air gap 3702a is created in the lower section 3701a of the substrate 3701 of the 20 dB directional coupler unit 3700 using a dicing mechanism. For example, a generally rectangular slot 3702 is made in the lower section 3701a of the substrate 3701 by removing a portion of the substrate 3701 from the lower section 3701a of the substrate 3701 using a dicing blade for creating the air gap 3702a.

In an embodiment, the 20 dB directional coupler unit 3700 can be a standalone unit or the substrate 3701 of the 20 dB directional coupler unit 3700 can be inserted into a connectorized housing (not shown), similar to the power divider unit 3200 disclosed in the detailed description of FIGS. 32A-32B. An input port 3704d, a coupled port 3704a, an isolated port 3704b, and an output port 3704c are positioned on the upper section 3701b of the substrate 3701. The input port 3704d, the coupled port 3704a, the isolated port 3704b, and the output port 3704c are configured to house the connector tabs 3708, 3705, 3706, and 3707 respectively, or to attach to a pin of each of one or more coaxial connectors (not shown). After the design of the electronic circuitry 3710 of the 20 dB directional coupler unit 3700 is fabricated on the upper section 3701b of the substrate 3701, a layer of epoxy 3703 is screen printed on the upper section 3701b of the substrate 3701, excluding the locations of the coupled port 3704a, the isolated port 3704b, the output port 3704c, and the input port 3704d of the 20 dB directional coupler unit 3700, similar to the termination chip 200 disclosed in the detailed description of FIGS. 2A-2C. The upper section 3701b of the substrate 3701 is covered with the layer of epoxy 3703 to protect the directional coupler unit 3700 from the external environment, after the 20 dB directional coupler unit 3700 has been configured. An opening 3709 is provided in the mid-section 3703a of the layer of epoxy 3703 for improving the performance of the 20 dB directional coupler unit 3700. The connector tabs 3705, 3706, 3707, and 3708 are then attached to the coupled port 3704a, the isolated port 3704b, the output port 3704c, and the input port 3704d of the 20 dB directional coupler unit 3700 respectively. In an embodiment, if the 20 dB directional coupler unit 3700 is to be inserted into a connectorized housing, then the ports 3704a, 3704b, 3704c, and 3704d can be left unattached, so that the ports 3704a, 3704b, 3704c, and 3704d can be attached to a pin of each of one or more coaxial connectors, similar to the termination chip 200 disclosed in the detailed description of FIGS. 2A-2E, the attenuator chip 1200 disclosed in the detailed description of FIGS. 12A-12B, and the power divider unit 3200 disclosed in the detailed description of FIGS. 32A-32B.

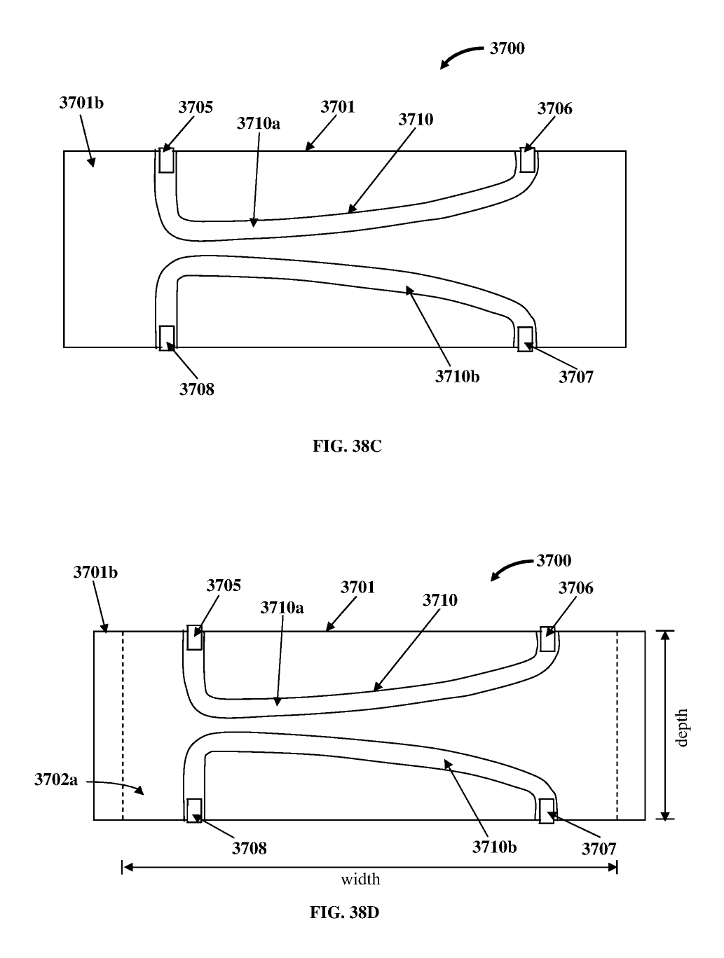

FIGS. 38A-38D exemplarily illustrate different views of a 20 dB directional coupler unit 3700, showing the electronic circuitry 3710 of the 20 dB directional coupler unit 3700. FIG. 38A exemplarily illustrates a top perspective view of the 20 dB directional coupler unit 3700, showing the electronic circuitry 3710 of the 20 dB directional coupler unit 3700. The method disclosed herein fabricates the electronic circuitry 3710 of a 20 dB directional coupler on an upper section 3701b of the substrate 3701 of the 20 dB directional coupler unit 3700. FIG. 38B exemplarily illustrates an enlarged view of a portion marked “B” of the 20 dB directional coupler unit 3700 shown in FIG. 38A. FIG. 38B exemplarily illustrates the air gap 3702a created in the lower section 3701a of the substrate 3701 of the 20 dB directional coupler unit 3700. The layer of epoxy 3703 is not shown in FIGS. 38A-38D.

FIG. 38C exemplarily illustrates a top plan view of the 20 dB directional coupler unit 3700, showing the electronic circuitry 3710 of the 20 dB directional coupler unit 3700. The electronic circuitry 3710 of the 20 dB directional coupler unit 3700 comprises a coupled transmission line 3710a, a main transmission line 3710b, the coupled connector tab 3705, the isolated connector tab 3706, the output connector tab 3707, and the input connector tab 3708. Power on the coupled transmission line 3710a flows in a direction opposite to power on the main transmission line 3710b. FIG. 38D exemplarily illustrates a top plan view of the 20 dB directional coupler unit 3700, showing the electronic circuitry 3710 of the 20 dB directional coupler unit 3700 and an air gap 3702a in hidden lines in the 20 dB directional coupler unit 3700. Example dimensions of the air gap 3702a of the 20 dB directional coupler unit 3700 exemplarily illustrated in FIG. 38D are width=1720.0 mils; length=5.0 mils; and depth=560.0 mils. These dimensions can be adjusted depending on the power, frequency, and electrical specifications of the directional coupler unit 3700. The layer of epoxy 3703 exemplarily illustrated in FIG. 37, is not shown in FIGS. 38A-38D.

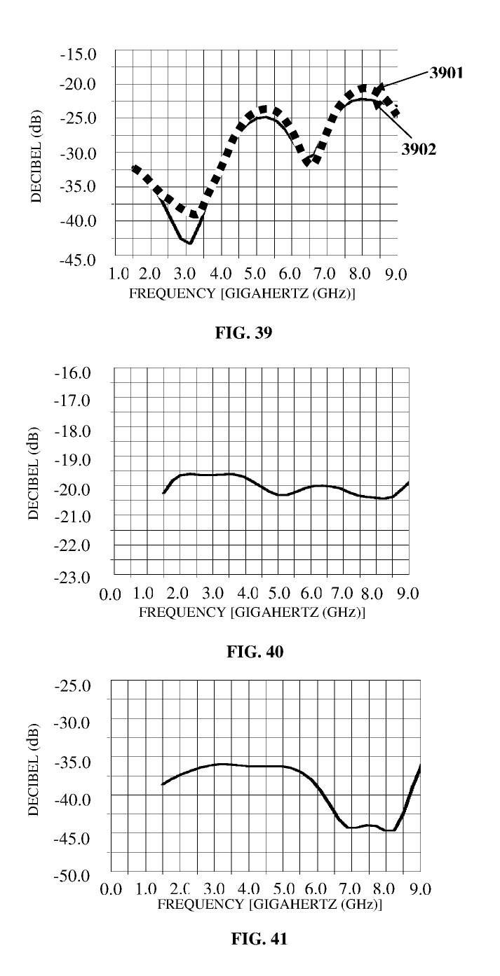

FIG. 39 exemplarily illustrates a graphical representation of return losses of the 20 dB directional coupler unit 3700 exemplarily illustrated in FIG. 37 and FIGS. 38A-38D over a frequency range. A simulation is performed by using a high frequency structural simulator (HFSS) to evaluate the design of the 20 dB directional coupler unit 3700. The improvement obtained through the introduction of the air gap 3702a in the substrate 3701 exemplarily illustrated in FIG. 37 and FIGS. 38A-38D, is exemplarily illustrated in FIG. 39. The curve 3901 exemplarily illustrates the return loss of the output connector tab 3707 and the isolated connector tab 3706 of the electronic circuitry 3710 of the 20 dB directional coupler unit 3700 exemplarily illustrated in FIG. 37 and FIGS. 38A-38D. The return loss for the output connector tab 3707 and the isolated connector tab 3706 is, for example, more than about 20 dB. The curve 3902 exemplarily illustrates the return loss of the input connector tab 3708 and the coupled connector tab 3705 of the electronic circuitry 3710 of the 20 dB directional coupler unit 3700 exemplarily illustrated in FIG. 37 and FIGS. 38A-38D. The return loss of the input connector tab 3708 and the coupled connector tab 3705 is, for example, more than about 22 dB. The benefit of reducing the insertion loss and the capacitance of the 20 dB directional coupler unit 3700 on the effect of return losses of the 20 dB directional coupler unit 3700 is exemplarily illustrated in FIG. 39.

FIG. 40 exemplarily illustrates a graphical representation of coupling performance of the 20 dB directional coupler unit 3700 exemplarily illustrated in FIG. 37 and FIGS. 38A-38D, over a frequency range. A simulation is performed by using a high frequency structural simulator (HFSS) to evaluate the design of the 20 dB directional coupler unit 3700. The improvement obtained through the introduction of the air gap 3702a in the substrate 3701 exemplarily illustrated in FIG. 37 and FIGS. 38A-38D, is exemplarily illustrated in FIG. 40. The benefit of reducing the insertion loss and the capacitance of the 20 dB directional coupler unit 3700 is exemplarily illustrated in FIG. 40. The frequency sensitivity of the 20 dB directional coupler unit 3700 is, for example, within a range of about +/−0.5 dB.

FIG. 41 exemplarily illustrates a graphical representation of isolation performance of the 20 dB directional coupler unit 3700 exemplarily illustrated in FIG. 37 and FIGS. 38A-38D, over a frequency range. A simulation is performed by using a high frequency structural simulator (HFSS) to evaluate the design of the 20 dB directional coupler unit 3700. The improvement obtained through the introduction of the air gap 3702a in the substrate 3701 exemplarily illustrated in FIG. 37 and FIGS. 38A-38D, is exemplarily illustrated in FIG. 41. The effect of reducing the capacitance, which in return provides the benefit of equalizing odd mode velocity and even mode velocity of the 20 dB directional coupler unit 3700 is exemplarily illustrated in FIG. 41. As used herein, “even mode velocity” refers to a propagation phase velocity of transmission lines of a directional coupler in an even mode. Also, as used herein, “odd mode velocity” refers to a propagation phase velocity of transmission lines of a directional coupler in an odd mode. Equalization of the odd mode velocity and the even mode velocity of the 20 dB directional coupler unit 3700 results in an isolation that is, for example, more than about 36 dB, thereby providing a directivity of about 16 dB. As used herein, the term “directivity” refers to a parameter that relates to isolation of a directional coupler. The directivity of a directional coupler is determined based on isolation and coupling measurements of the directional coupler.

The foregoing examples have been provided merely for the purpose of explanation and are in no way to be construed as limiting of the present invention disclosed herein. While the invention has been described with reference to various embodiments, it is understood that the words, which have been used herein, are words of description and illustration, rather than words of limitation. Further, although the invention has been described herein with reference to particular means, materials, and embodiments, the invention is not intended to be limited to the particulars disclosed herein; rather, the invention extends to all functionally equivalent structures, methods and uses, such as are within the scope of the appended claims. Those skilled in the art, having the benefit of the teachings of this specification, may effect numerous modifications thereto and changes may be made without departing from the scope and spirit of the invention in its aspects.

I claim:

1. A method for creating an air gap in a passive electronic component chip configured for high frequency microwave transmission, said method comprising:
providing a substrate of a single layer configured to house an electronic circuitry of said passive electronic component chip;
fabricating said electronic circuitry of said passive electronic component chip on a top surface of said substrate;
determining a plurality of locations on a bottom surface of said substrate for creating said air gap, wherein said locations are located below resistive regions on said top surface of said substrate; and
creating said air gap of a pre-determined dimension at one of said locations on said bottom surface of said substrate by dicing said substrate at said one of said pre-determined locations, wherein said air gap creates an air cushion for said passive electronic component chip thereby simulating a suspended substrate environment, and wherein said air gap below said resistive regions at said one of said locations is created to obtain a pre-determined dielectric constant for said passive electronic component chip.

2. The method of claim 1, further comprising creating one or more additional air gaps of a plurality of pre-determined dimensions at one or more of said determined locations on said substrate by dicing said substrate at said one or more of said determined locations, wherein said one or more additional air gaps are configured to adjust power dissipation and performance of said passive electronic component chip.

3. The method of claim 1, wherein said passive electronic component chip is configured as one of a termination chip, an attenuator chip, a power divider unit, a resistor, a directional coupler unit, a hybrid coupler unit, and a filter.

4. The method of claim 1, further comprising configuring one or more ports in said top surface of said substrate of said passive electronic component chip, wherein said one or more ports house one or more connector tabs of said passive electronic component chip or attach to a pin of each of one or more coaxial connectors.

5. The method of claim 1, further comprising configuring one or more vias in said substrate of said passive electronic component chip, wherein said one or more vias are configured to increase power dissipation of said passive electronic component chip by allowing a ground connection of said electronic circuitry from an upper section of said passive electronic component chip to a metalized lower section of said passive electronic component chip through said one or more vias.

6. The method of claim 1, wherein said substrate is a ceramic substrate.

7. A method for creating one or more air gaps in a passive electronic component chip configured for high frequency microwave transmission, said method comprising:
determining a configuration for an electronic circuitry of a passive electronic component chip for obtaining a pre-determined dielectric constant of said passive electronic component chip;
providing a substrate of a single layer configured to house said electronic circuitry of said passive electronic component chip in said determined configuration, said passive electronic component chip comprising a plurality of passive electronic components;
fabricating said electronic circuitry of said passive electronic component chip in said determined configuration on a top surface of said substrate;
determining a plurality of locations on a bottom surface of said substrate for creating said one or more air gaps, wherein said locations are located below resistive regions on said top surface of said substrate; and
creating said air gap of pre-determined dimensions at said determined locations on said bottom surface of said substrate by dicing said substrate at said locations, said pre-determined dimensions of each of said one or more air gaps are determined based on power and frequency requirement of one or more of said plurality of passive electronic components of said passive electronic component chip, wherein said one or more air gaps are configured to create an air cushion for said one or more of said passive electronic components thereby simulating a suspended substrate environment. and wherein said air gap below said resistive regions at said one of said locations is created to obtain a pre-determined dielectric constant for said passive electronic component chip.

8. The method of claim 7, wherein said pre-determined dimensions of said one or more air gaps are based on design considerations used for fabricating said passive electronic component chip, wherein said design considerations comprise adjustment of power dissipation and performance of said passive electronic component chip.

9. The method of claim 7, wherein said passive electronic component chip is configured as one of a termination chip, an attenuator chip, a power divider unit, a resistor, a directional coupler unit, a hybrid coupler unit, and a filter.

10. The method of claim 7, further comprising configuring one or more ports in said top surface of said substrate of said passive electronic component chip, wherein said one or more ports house one or more connector tabs of said passive electronic component chip or attach to a pin of each of one or more coaxial connectors.

11. The method of claim 7, further comprising configuring one or more vias in said single layer of said substrate of said passive electronic component chip, wherein said one or more vias are configured to increase power dissipation of said passive electronic component chip by allowing a ground connection of said electronic circuitry from an upper section of said passive electronic component chip to a metalized lower section of said passive electronic component chip through said one or more vias.

12. The method of claim 7, wherein said substrate is a ceramic substrate.

13. A method for creating one or more air gaps in a passive electronic component chip configured for high frequency microwave transmission, said method comprising:
providing a substrate having a single layer configured to house an electronic circuitry of said passive electronic component chip;
fabricating said electronic circuitry on a top surface of said substrate;
providing one or more dicing paths at one or more selected locations on a bottom surface of said substrate, wherein said one or more selected locations are determined based on one or more resistive regions on said top surface of said substrate, wherein said one or more resistive regions are areas of high capacitance of said electronic circuitry; and
creating one or more air gaps of pre-determined dimensions at said one or more dicing paths on said bottom surface of said substrate, wherein said one or more air gaps are formed by dicing said bottom surface at said one or more dicing paths, wherein said diced one or more air gaps create an air cushion for said passive electronic component chip thereby simulating a suspended substrate environment.
